(19) United States
(12) Patent Application Publication
(10) Pub. No.: US 2025/0040404 A1
(43) Pub. Date: Jan. 30, 2025

(54) DISPLAY DEVICE AND METHOD OF PROVIDING THE SAME

(71) Applicant: Samsung Display Co., LTD., Yongin-si (KR)

(72) Inventors: Che Ho LEE, Yongin-si (KR); So Yeon JEONG, Yongin-si (KR); Won Je JO, Yongin-si (KR); Jae Hyun KIM, Yongin-si (KR); Kwan Hee LEE, Yongin-si (KR); Young Seo CHOI, Yongin-si (KR)

(21) Appl. No.: 18/439,919

(22) Filed: Feb. 13, 2024

(30) Foreign Application Priority Data
Jul. 26, 2023 (KR) 10-2023-0097311

(51) Int. Cl. H10K 59/80; H10K 59/12; H10K 59/122

(52) U.S. Cl. CPC H10K 59/873; H10K 59/1201; H10K 59/122

(57) ABSTRACT

A display device includes a bank including first and second bank layers each having side surfaces respectively defining bank openings corresponding to light emission areas, the second bank layer protruding further than the side surfaces of the first bank layer to define tips of the second bank layer and an upper surface at the tips, an inorganic encapsulation layer on the bank and including first and second patterns each having a body corresponding to the light emission areas and a wing portion extended from the body, the wing portions overlapping each other and spaced apart from the upper surface at the tips, the second pattern further including a connection portion which is connected to the body and the first wing portion of the second pattern and is between the first wing portion of the first pattern and the second bank layer.

This application claims priority to Korean Patent Application No. 10-2023-0097311, filed on Jul. 26, 2023, and all the benefits accruing therefrom under 35 U.S.C. § 119, the disclosure of which is incorporated herein in its entirety by reference.

### BACKGROUND

### 1. Field

The present disclosure relates to a display device and a method of providing the same.

### 2. Description of the Related Art

As the information society develops, demands for display devices for displaying images are increasing in various forms. For example, display devices are applied to various electronic devices such as smartphones, digital cameras, notebook computers, navigation devices, and smart televisions. The display devices may be flat panel display devices such as liquid crystal display devices, field emission display devices, and organic light emitting display devices. Among these flat panel display devices, a light emitting display device includes a light emitting element which enables each pixel of a display panel to emit light by itself. Thus, the light emitting display device can display an image without a backlight unit which provides light to the display panel.

Display devices have been applied to eyeglasses-like devices for providing virtual reality and augmented reality. To be applied to an eyeglasses-like device, a display device is implemented in a very small size of two inches or less.

### SUMMARY

Where a relatively small display device is applied to an electronic device, the display device has a high pixel density to have high resolution. For example, the display device applied to an eyeglasses-like device may have a high pixel density of 400 pixels per inch (PPI) or more. When the display device is implemented in a very small size but has a high pixel density as described above, it may be difficult to implement a separate light emitting element in each light emission area of the display device through a mask process since the planar area of the light emission area in which the light emitting element is disposed is reduced.

Aspects of the present disclosure provide a display device in which a separate light emitting element can be formed in each emission area without a mask process.

Aspects of the present disclosure also provide a display device having improved encapsulation reliability at a tip of a second bank layer.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an embodiment of the disclosure, a display device includes a first pixel electrode and a second pixel electrode spaced apart from each other on a substrate, a pixel defining layer disposed on the substrate and exposing the first pixel electrode and the second pixel electrode, a first light emitting layer on the first pixel electrode and a first common electrode on the first light emitting layer, a second light emitting layer on the second pixel electrode and a second common electrode on the second light emitting layer, a first bank layer disposed on the pixel defining layer, a second bank layer disposed on the first bank layer and including side surfaces protruding more than side surfaces of the first bank layer, a first inorganic layer including a body portion disposed on the first common electrode and a first wing portion disposed on the second bank layer but spaced apart from an upper surface of the second bank layer, and a second inorganic layer including a body portion disposed on the second common electrode, a first connection portion disposed between the first wing portion of the first inorganic layer and the second bank layer, and a first wing portion disposed on the first wing portion of the first inorganic layer.

The first inorganic layer may further include a second wing portion connecting the body portion of the first inorganic layer and the first wing portion of the first inorganic layer and spaced apart from the upper surface of the second bank layer, where the first wing portion of the first inorganic layer may include a first side surface overlapping the first light emitting layer and a second side surface opposite the first side surface, the second wing portion of the first inorganic layer may include a first side surface overlapping the first light emitting layer and a second side surface opposite the first side surface, and the second side surface of the first wing portion of the first inorganic layer may protrude more than the second side surface of the second wing portion of the first inorganic layer.

The first wing portion of the second inorganic layer may be spaced apart from the first wing portion of the first inorganic layer.

The second inorganic layer may further include a third wing portion protruding from the first connection portion of the second inorganic layer in a thickness of the substrate and a second wing portion connecting the third wing portion of the second inorganic layer and the first wing portion of the second inorganic layer, where the first wing portion of the second inorganic layer may include a first side surface adjacent to the second light emitting layer and a second side surface opposite the first side surface, the second wing portion of the second inorganic layer may include a first side surface adjacent to the second light emitting layer and a second side surface opposite the first side surface, and the second side surface of the first wing portion of the second inorganic layer may protrude more than the second side surface of the second wing portion of the second inorganic layer.

The display device may further include a void space between the second wing portion of the first inorganic layer and the second bank layer.

The second inorganic layer may further include a second connection portion connected to the first connection portion of the second inorganic layer and disposed on the second side surface of the second wing portion of the first inorganic layer and a third connection portion connecting the second connection portion of the second inorganic layer and the body portion of the second inorganic layer.

The display device may further include a second organic pattern disposed on the second bank layer and including the same material as the second light emitting layer, where a portion of the second bank layer may contact the third connection portion of the second inorganic layer, and another portion of the second bank layer may contact the second organic pattern.

The first connection portion of the second inorganic layer may contact a lower surface of the first wing portion of the first inorganic layer, and the second connection portion of the second inorganic layer may contact the second side surface of the second wing portion of the first inorganic layer.

A thickness of the first wing portion of the first inorganic layer may be smaller than a thickness of the second wing portion of the first inorganic layer.

A distance between the first wing portion of the first inorganic layer and the first wing portion of the second inorganic layer may be greater than a distance between the second pixel electrode and the body portion of the second inorganic layer.

A distance between the second bank layer and the second wing portion of the first inorganic layer may be equal to a distance between the first pixel electrode and the body portion of the first inorganic layer.

The display device may further include an organic encapsulation layer disposed between the first wing portion of the first inorganic layer and the first wing portion of the second inorganic layer.

The body portion of the first inorganic layer may include silicon (Si), oxygen (O) and nitrogen (N), and the first wing portion of the first inorganic layer may include silicon (Si) and oxygen (O).

The first wing portion of the first inorganic layer may include silicon (Si) and oxygen (O), and the first connection portion of the second inorganic layer may include silicon (Si) and nitrogen (N).

The first common electrode and the second common electrode may be spaced apart from each other and contact the side surfaces of the first bank layer.

The display device may further include residual patterns disposed between the pixel defining layer and the first pixel electrode and between the pixel defining layer and the second pixel electrode.

According to an embodiment of the disclosure, a method of fabricating (or providing) a display device includes forming (or providing) pixel electrodes spaced apart from each other on a substrate, forming a sacrificial layer on each of the pixel electrodes, forming a pixel defining material layer on the sacrificial layers, forming a first bank material layer on the pixel defining material layer, and forming a second bank material layer on the first bank material layer, exposing the pixel defining material layer by etching the first bank material layer and the second bank material in areas overlapping the pixel electrodes, etching side surfaces of the first bank material layer to partially expose a lower surface of the second bank material layer, exposing the pixel electrodes by etching the exposed pixel defining material layer and the sacrificial layers, forming a first light emitting layer on a first pixel electrode among the pixel electrodes and forming a first light emitting material layer on the second bank material layer, forming a first common electrode on the first light emitting layer and forming a first electrode material layer on the first light emitting material layer, forming a first inorganic material layer on the first common electrode and the first electrode material layer, and forming a mask pattern on the first inorganic material layer overlapping the first pixel electrode and removing the first inorganic material layer not covered by the mask pattern and a portion of the first inorganic material layer covered by the mask pattern.

In the forming of the mask pattern on the first inorganic material layer overlapping the first pixel electrode and the removing of the first inorganic material layer not covered by the mask pattern and the portion of the first inorganic material layer covered by the mask pattern, protruding side surfaces of the first inorganic material layer may be formed by removing silicon nitride or silicon oxynitride using an isotropic etching process.

The method of fabricating a display device may further include etching the first electrode material layer and the first light emitting material layer, forming a second light emitting layer on a second pixel electrode among the pixel electrodes and forming a second light emitting material layer on the second bank material layer and the first inorganic material layer, forming a second common electrode on the second light emitting layer and forming a second electrode material layer on the second light emitting material layer, and forming a second inorganic material layer on the second common electrode, the second electrode material layer, the second bank material layer, and the first inorganic material layer.

The forming of the second light emitting material layer on the second bank material layer and the first inorganic material layer may include letting a light emitting material deposited on the substrate be separated by the protruding side surfaces of the first inorganic material layer, and the forming of the second inorganic material layer on the second common electrode, the second electrode material layer, the second bank material layer and the first inorganic material layer may include forming a second inorganic material layer between the second bank material layer and the first inorganic material layer.

In accordance with the display device and the method for fabrication thereof according to one embodiment, a lower inorganic encapsulation layer includes wing portions on a second bank layer and adjacent lower inorganic encapsulation layers can cover upper and lower part of the wing portions. Since sealing between the lower inorganic encapsulation layer and the light emitting device is excellent, reliability of the display device can be improved.

However, effects according to the embodiments of the present disclosure are not limited to those exemplified above and various other effects are incorporated herein.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a display device according to an embodiment;

FIG. 2 is a cross-sectional view of the display device of FIG. 1 as viewed from the side;

FIG. 3 is a plan view illustrating the arrangement of emission areas in the display device according to the embodiment;

FIG. 4 is an exploded perspective view illustrating lamination of a light emitting element layer relative to a lower inorganic encapsulation layer in area B of FIG. 3;

FIG. 5 is a cross-sectional view of a portion of the display device according to the embodiment;

FIG. 6 is an enlarged cross-sectional view of area A1 of FIG. 5;

FIG. 7 is a flowchart illustrating a process of providing (or fabricating) a display device according to an embodiment; and

FIGS. 8 through 20 are cross-sectional views illustrating processes in a method of providing (or fabricating) the display device according to the embodiment.

### DETAILED DESCRIPTION

The invention will now be described more fully hereinafter with reference to the accompanying drawings, in which embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being related to another element such as being “on” another layer or substrate, it can be directly on the other layer or substrate, or intervening layers may also be present. In contrast, when a layer is referred to as being related to another element such as being “directly on” another layer or substrate, no other layer, substrate, or intervening layers is present therebetween.

The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described with reference to the accompanying drawings.

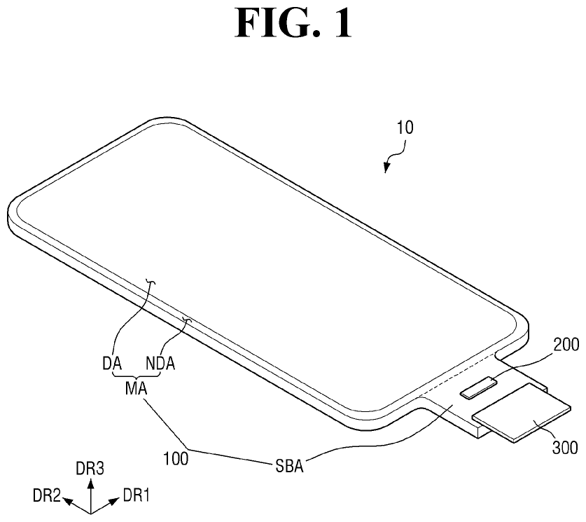

FIG. 1 is a perspective view of a display device 10 according to an embodiment.

Referring to FIG. 1, the display device 10 according to the embodiment may be included in an electronic device to provide a display screen at which an image is displayed by the electronic device. The electronic device may refer to any electronic device which provides a display screen. Examples of the electronic device may include televisions, notebook computers, monitors, billboards, Internet of things (IoT) devices, mobile phones, smartphones, tablet personal computers (PCs), electronic watches, smart glasses, smart watches, watch phones, head mounted displays, mobile communication terminals, electronic notebooks, electronic books, portable multimedia players (PMPs), navigation devices, game machines, digital cameras and camcorders, all of which provide a display screen.

The shape of the display device 10 can be variously modified. For example, the display device 10 may have a planar shape similar to a rectangle having short sides extended in a first direction DR1 and long sides extended in a second direction DR2 crossing the first direction DR1. Each corner where a short side extending in the first direction DR1 meets a long side extending in the second direction DR2 may be rounded with a curvature in the plan view. However, the present disclosure is not limited thereto, and a corner may also be right-angled. The planar shape of the display device 10 is not limited to a quadrangular shape but may also be similar to other polygonal shapes, a circular shape, or an oval shape.

The display device 10 may include a display panel 100, a display driver 200, a circuit board 300, and a touch driver 400.

The display panel 100 may include a main area MA and a sub-area SBA.

The main area MA may include a display area DA including pixels which display an image, and a non-display area NDA which is adjacent to the display area DA. In an embodiment, the non-display area NDA is disposed around the display area DA in the plan view. The display area DA may emit light from a plurality of emission areas or a plurality of opening areas (e.g., a light emission area provided in plural including a plurality of light emission areas). For example, the display panel 100 may include pixel circuits including switching elements, a pixel defining layer defining the emission areas and/or the opening areas, and self-light emitting elements connected to the pixel circuits.

For example, each of the self-light emitting elements as a light emitting element may include, but is not limited to, at least one of an organic light emitting diode including an organic light emitting layer, a quantum dot light emitting diode including a quantum dot light emitting layer, an inorganic light emitting diode including an inorganic semiconductor, and a micro-light emitting diode.

A plurality of pixels, a plurality of scan lines, a plurality of data lines, and a plurality of power lines may be disposed in the display area DA. Each of the pixels may be defined as a minimum unit which emits light, displays an image, etc., and the above-described self-light emitting elements may be in the pixels, respectively. The light emitting elements may correspond to or define the pixels, however, are not limited thereto. The scan lines as signal lines may supply scan signals as electrical signals received from a scan driver, to the pixels. The data lines as signal lines may supply data voltages as electrical signals received from the display driver 200, to the pixels. The power lines as signal lines may supply a power supply voltage as an electrical signal received from the display driver 200, to the pixels.

The non-display area NDA may be an area (e.g., a planar area) outside the display area DA, such as to be closer to an outer edge of the display device 10 than the display area DA. The non-display area NDA may be defined as an edge area of the main area MA of the display panel 100. The non-display area NDA may include the scan driver which supplies scan signals to the scan lines and fan-out lines which connect the display driver 200 and the display area DA.

The sub-area SBA may extend from a side of the main area MA. The sub-area SBA may include a flexible material which can be bent, folded, rolled, etc. For example, when the display device 10 is bent at the sub-area SBA, the sub-area SBA may be overlapped by the main area MA in (or along) a thickness direction (e.g., the third direction DR3). That is, a thickness of the display device 10 and various components or layers thereof may be defined along the third direction DR3 which intersects the plane defined by the first direction DR1 and the second direction DR2 crossing each other. The sub-area SBA may include the display driver 200 and a pad unit which is connected to the circuit board 300. In an embodiment, the sub-area SBA may be omitted, and the display driver 200 and the pad unit may be disposed in the non-display area NDA. In an embodiment, the sub-area SBA may be a portion of the non-display area NDA.

The display driver 200 may output signals and voltages for driving the display panel 100. The display driver 200 may supply data voltages to the data lines. The display driver 200 may supply a power supply voltage to the power lines and supply a scan control signal to the scan driver. The display driver 200 may be formed (or provided) as an integrated circuit and mounted on the display panel 100 such as by a chip on glass (COG) method, a chip on plastic (COP) method, or an ultrasonic bonding method. For example, the display driver 200 may be disposed in the sub-area SBA and may be overlapped by the main area MA in the thickness direction (third direction DR3) within the display device 10 which is bent at the sub-area SBA. For another example, the display driver 200 may be mounted on the circuit board 300.

The circuit board 300 may be attached onto a pad unit of the display panel 100 such as by using an anisotropic conductive film (ACF). Lead lines of the circuit board 300 may be electrically connected to the display panel 100 at the pad unit thereof. The circuit board 300 may be a flexible printed circuit board, a printed circuit board, or a flexible film such as a chip on film.

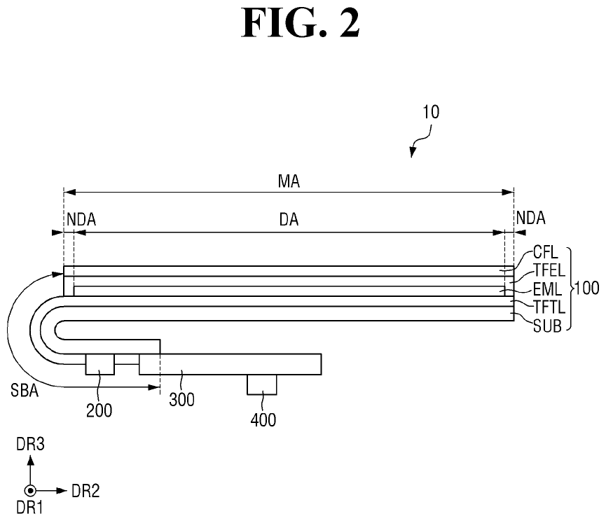

FIG. 2 is a cross-sectional view of the display device 10 of FIG. 1 as viewed from the side. Specifically, FIG. 2 illustrates a side of the display device 10 of FIG. 1 in a folded state. The display device 10 and various components or layers thereof may be bendable, foldable, rollable, etc., such as to be deformed together with each other.

Referring to FIG. 2, the display panel 100 may include a substrate SUB, a thin-film transistor layer TFTL as a circuit layer, a light emitting element layer EML, a thin-film encapsulation layer TFEL as an encapsulation layer, and a color filter layer CFL as a color control layer.

The substrate SUB may be a base substrate or a base member. The substrate SUB may be a flexible substrate which can be bent, folded, rolled, etc. For example, the substrate SUB may include polymer resin such as polyimide (PI), but the present disclosure is not limited thereto. In an embodiment, the substrate SUB may include a glass material or a metal material.

The thin-film transistor layer TFTL may be disposed on the substrate SUB. The thin-film transistor layer TFTL may include a plurality of thin-film transistors constituting pixel circuits of pixels. The thin-film transistor layer TFTL may further include scan lines, data lines, power lines, scan control lines, fan-out lines connecting the display driver 200 and the data lines to each other, and lead lines connecting the display driver 200 and the pad unit to each other. Each of the thin-film transistors may include a semiconductor region, a source electrode, a drain electrode, and a gate electrode. For example, when the scan driver as a driver is formed (or provided) on a side of the non-display area NDA of the display panel 100, the driver may include thin-film transistors.

The thin-film transistor layer TFTL may be disposed in the display area DA, the non-display area NDA, and the sub-area SBA. The thin-film transistors of the pixels, the scan lines, the data lines, and the power lines of the thin-film transistor layer TFTL may be disposed in the display area DA. The scan control lines and the fan-out lines of the thin-film transistor layer TFTL may be disposed in the non-display area NDA. The lead lines of the thin-film transistor layer TFTL may be disposed in the sub-area SBA.

The light emitting element layer EML may be disposed on the thin-film transistor layer TFTL. The light emitting element layer EML may include a plurality of light emitting elements, each including a first electrode, a second electrode and a light emitting layer to emit light, and a pixel defining layer which defines the pixels. The light emitting elements of the light emitting element layer EML may be disposed in the display area DA. The light emitting element layer EML may be electrically connected to the circuit layer (e.g., the thin-film transistor layer TFTL) to emit light, display an image with light, etc.

In an embodiment, the light emitting layer may be an organic light emitting layer including an organic material. The light emitting layer may include a hole transporting layer, an organic light emitting layer, and an electron transporting layer. When the first electrode receives a voltage through a thin-film transistor of the thin-film transistor layer TFTL and the second electrode receives a cathode voltage, holes and electrons may move to the organic light emitting layer through the hole transporting layer and the electron transporting layer, respectively. Then, the holes and the electrons may be combined with each other in the organic light emitting layer to emit light.

In an embodiment, each of the light emitting elements may include a quantum dot light emitting diode including a quantum dot light emitting layer, an inorganic light emitting diode including an inorganic semiconductor, or a micro-light emitting diode.

The thin-film encapsulation layer TFEL may cover upper and side surfaces of the light emitting element layer EMIL and may protect the light emitting element layer EML from an environment outside of the thin-film transistor layer TFTL. The thin-film encapsulation layer TFEL may include at least one inorganic layer together with at least one organic layer to encapsulate the light emitting element layer EML.

The color filter layer CFL may be disposed on the thin-film encapsulation layer TFEL. The color filter layer CFL may include a plurality of color filters corresponding to a plurality of emission areas, respectively. Each of the color filters may selectively transmit light of a specific wavelength and block or absorb light of other wavelengths, such as to color control the light. The color filter layer CFL may absorb a part of external light coming from the outside of the display device 10, thereby reducing reflected light caused by the external light. Therefore, the color filter layer CFL may prevent color distortion caused by reflection of external light, to further control light.

In an embodiment, since the color filter layer CFL is directly disposed on the thin-film encapsulation layer TFEL, the display device 10 may not require a separate substrate for the color filter layer CFL. Therefore, an overall thickness of the display device 10 may be relatively small.

In some embodiments, the display device 10 may further include an optical device which provides a function to the display device 10 as a functional component thereof. The optical device may emit or receive light in infrared, ultraviolet, and visible light bands to provide the function. For example, the optical device may be an optical sensor which senses light incident on the display device 10 to provide a light-sensing function, such as a proximity sensor to provide a proximity-sensing function, an illuminance sensor to provide a light-sensing function, a camera sensor to capture an image, a fingerprint sensor to detect a fingerprint, or an image sensor to detect an image.

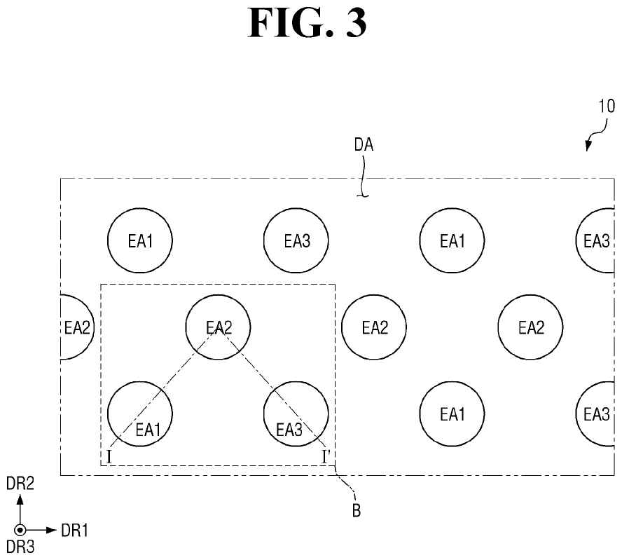

FIG. 3 is a plan view of a portion of the display device 10 according to the embodiment. FIG. 3 is a plan view illustrating the arrangement of emission areas EA1 through EA3 in the display area DA of the display device 10.

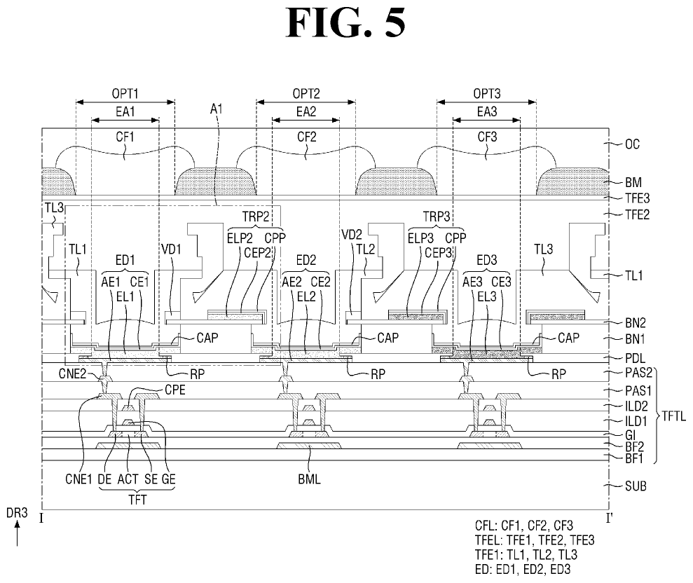

Referring to FIG. 3, the display device 10 may include a plurality of emission areas EA1 through EA3 disposed in the display area DA. The emission areas EA1 through EA3 may include first emission areas EA1, second emission areas EA2, and third emission areas EA3 at which light of different colors is emitted. Each of the first through third emission areas EA1 through EA3 may emit red, green or blue light. The color of light respectively emitted from each of the emission areas EA1 through EA3 may vary according to the type of light emitting element ED1, ED2 or ED3 (see FIG. 5) which will be described later. For example, the first emission areas EA1 may emit red first light, the second emission areas EA2 may emit green second light, and the third emission areas EA3 may emit blue third light. However, the present disclosure is not limited thereto.

The emission areas EA1 through EA3 may be arranged in a PenTile™ type, for example, a diamond PenTile™ type. For example, the first emission areas EA1 and the third emission areas EA3 may be spaced apart from each other in the first direction DR1 and may be alternately disposed with each other in the first direction DR1. The emission areas within a column of the first emission areas EA1 or the third emission areas EA3 may be spaced apart from each other along the second direction DR2. Adjacent columns (or adjacent rows) of emission areas may be spaced apart from each other along the first direction DR1 (or the second column). Each of the second emission areas EA2 may be spaced apart from another adjacent second emission areas EA2, in the first direction DR1 and the second direction DR2. The second emission areas EA2 and the first emission areas EA1 or the second emission areas EA2 and the third emission areas EA3 may be alternately disposed with each other along any single direction along the plane formed by the first direction DR1 and the second direction DR2 crossing each other. In an embodiment, a sequence of three different color emission areas may be arranged along a direction inclined with respect to the first direction DR1 and/or the second direction DR2.

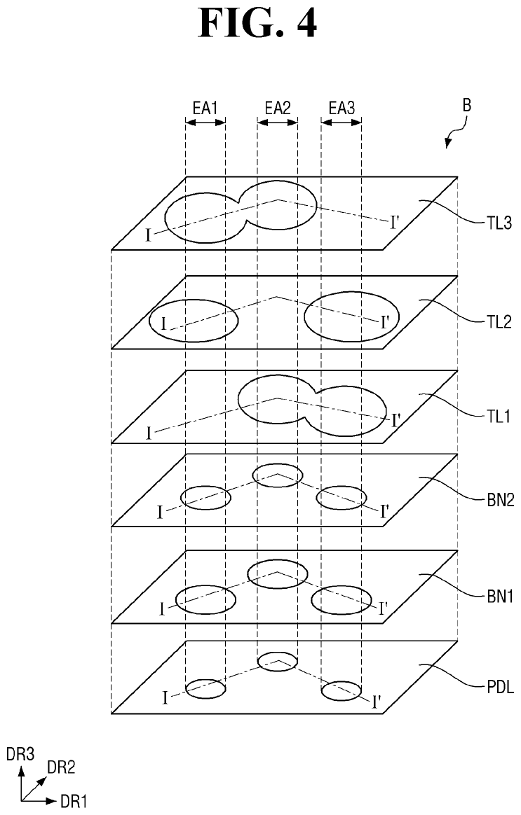

Each of the first through third emission areas EA1 through EA3 may be defined by a pixel defining layer PDL (see FIG. 4) which will be described later.

In the display device 10, a first emission area EA1, a second emission area EA2, and a third emission area EA3 disposed adjacent to each other may form one pixel group. Referring to FIG. 3, area B represents one pixel group. FIG. 4 is an exploded perspective view of area B of FIG. 3.

Referring to FIG. 4, the pixel defining layer PDL defines the first through third emission areas EA1 through EA3. Here, the pixel defining layer PDL may define a planar size, a planar shape, a planar location, etc. of the first through third emission areas EA1 through EA3. In FIG. 4, light emitting elements, a transistor layer, etc. are omitted for convenience of illustration.

A first bank layer BN1, a second bank layer BN2, and first through third inorganic layers TL1 through TL3 are sequentially stacked on the pixel defining layer PDL, to define a stacked structure on the pixel defining layer PDL. Within the stacked structure, exposed areas corresponding to the first through third emission areas EA1 through EA3 are defined in each of the first bank layer BN1, the second bank layer BN2, and the first through third inorganic layers TL1 through TL3. As used herein, an exposed area may correspond to an opening or hole in a layer or a material (solid) portion of the layer.

Exposed areas of the first bank layer BN1 may overlap the first through third emission areas EA1 through EA3 but may have a planar dimension which is larger than a planar dimension of the first through third emission areas EA1 through EA3, respectively.

Exposed areas of the second bank layer BN2 may overlap the first through third emission areas EA1 through EA3 but may have a planar dimension which is smaller than the exposed areas of the first bank layer BN1, respectively.

Exposed areas of the first inorganic layer TL1 may overlap the whole of the second and third emission areas EA2 and EA3. The exposed areas of the first inorganic layer TL1 which correspond to the second and third emission areas EA2 and EA3 may be connected to each other, such as being a single opening, to overlap an entirety of the second and third emission areas EA2 and EA3 together with a planar area which immediately surroundings the second and third emission areas EA2 and EA3.

Exposed areas of the second inorganic layer TL2 may overlap the whole of the first and third emission areas EA1 and EA3. The exposed areas of the second inorganic layer TL2 which correspond to the first and third emission areas EA1 and EA3 may be disconnected from each other so as to respectively overlap overlaps an entire planar area of the second and third emission areas EA2 and EA3 together with a planar area which immediately surroundings the first and third emission areas EA1 and EA3. In an embodiment, the exposed areas of the second inorganic layer TL2 which correspond to the first and third emission areas EA1 and EA3 may be connected to each other, such as to provide a single opening.

Exposed areas of the third inorganic layer TL3 may overlap the whole of the first and second emission areas EA1 and EA2.

FIG. 5 is a cross-sectional view of a portion of the display device 10 according to the embodiment. The horizontal direction of the view in FIG. 5 may represent any of a number of direction along the plane defined by the plane formed by the first direction DR1 and the second direction DR2 crossing each other. Specifically, FIG. 5 is a cross-sectional view of portion I-I′ within the various layers of FIGS. 3 and 4. FIG. 5 further illustrates an organic encapsulation layer TFE2, an upper inorganic encapsulation layer TFE3, color filters CF1 through CF3, a light blocking layer BM and an overcoat layer OC disposed on the third inorganic layer TL3 of FIG. 4, together with the thin-film transistor layer TFTL and the substrate SUB which are disposed under the pixel defining layer PDL. Referring to FIG. 5, the thin-film transistor layer TFTL, the light emitting element layer EML, the thin-film encapsulation layer TFEL and the color filter layer CFL may be sequentially stacked on the substrate SUB, that is, arranged in order in a direction from the substrate SUB.

The thin-film transistor layer TFTL may include a first buffer layer BF1, bottom metal layers BML as metal patterns of a metal pattern layer, a second buffer layer BF2, thin-film transistors TFT, a gate insulating layer GI, a first interlayer insulating layer ILD1, capacitor electrodes CPE, a second interlayer insulating layer ILD2, first connection electrodes CNE1, a first passivation layer PAS1, second connection electrodes CNE2, and a second passivation layer PAS2. One or more of the insulating layers mentioned above may be considered as “an insulating layer.”

The first buffer layer BF1 may be disposed on the substrate SUB. The first buffer layer BF1 may include an inorganic layer which can prevent permeation of air or moisture. For example, the first buffer layer BF1 may include a plurality of inorganic layers stacked alternately with each other.

The bottom metal layers BML may be disposed on the first buffer layer BF1. For example, each pattern among the bottom metal layers BML may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

The second buffer layer BF2 may cover the first buffer layer BF1 and the bottom metal layers BML. The second buffer layer BF2 may include an inorganic layer which can prevent permeation of air or moisture. For example, the second buffer layer BF2 may include a plurality of inorganic layers stacked alternately with each other.

The thin-film transistors TFT may be disposed on the second buffer layer BF2. The thin-film transistors TFT may constitute respective pixel circuits of a plurality of pixels. For example, each of the thin-film transistors TIFT may be a driving transistor or a switching transistor of a pixel circuit. Each of the thin-film transistors TFT may include a semiconductor layer ACT, a source electrode SE, a drain electrode DE, and a gate electrode GE.

The semiconductor layer ACT may be disposed on the second buffer layer BF2. The semiconductor layer ACT may overlap a bottom metal layer BML and the gate electrode GE in the thickness direction DR3 and may be insulated from the gate electrode GE by the gate insulating layer GI. In portions of the semiconductor layer ACT, the material of the semiconductor layer ACT may be made conductive to form the source electrode SE and the drain electrode DE.

The gate electrode GE may be disposed on the gate insulating layer GI. The gate electrode GE may overlap the semiconductor layer ACT in the thickness direction DR3 with the gate insulating layer GI interposed between them.

The gate insulating layer GI may be disposed on the semiconductor layers ACT. For example, the gate insulating layer GI may cover the semiconductor layers ACT and the second buffer layer BF2 and may insulate the semiconductor layers ACT from the gate electrodes GE. The gate insulating layer GI may include contact holes through which the first connection electrodes CNE1 pass. That is, contact holes may be defined in the gate insulating layer GI. As used herein, a contact hole may penetrate completely through a thickness of a respective layer, such as to be open at both an upper surface and a lower surface which is opposite to the upper surface of the respective layer.

The first interlayer insulating layer ILD1 may cover the gate electrodes GE and the gate insulating layer GI. The first interlayer insulating layer ILD1 may include (or define) contact holes through which the first connection electrodes CNE1 pass. The contact holes of the first interlayer insulating layer ILD1 may be connected to the contact holes of the gate insulating layer GI and to contact holes of the second interlayer insulating layer ILD2, such as to form a single respective contact hole.

The capacitor electrodes CPE may be disposed on the first interlayer insulating layer ILD1. The capacitor electrodes CPE may overlap the gate electrodes GE in the thickness direction DR3. The capacitor electrodes CPE and the gate electrodes GE may form electrical capacitance therebetween.

The second interlayer insulating layer ILD2 may cover the capacitor electrodes CPE and the first interlayer insulating layer ILD1. The second interlayer insulating layer ILD2 may include the contact holes through which the first connection electrodes CNE1 pass. The contact holes of the second interlayer insulating layer ILD2 may be connected to the contact holes of the first interlayer insulating layer ILD1 and the contact holes of the gate insulating layer GI.

The first connection electrodes CNE1 may be disposed on the second interlayer insulating layer ILD2. The first connection electrodes CNE1 may electrically connect the drain electrodes DE of the thin-film transistors TFT to the second connection electrodes CNE2. The first connection electrodes CNE1 may extend through the corresponding contact holes formed in the second interlayer insulating layer ILD2, the first interlayer insulating layer IL) and the gate insulating layer GI, to contact the drain electrodes DE of the thin-film transistors TFT.

The first passivation layer PAS1 may cover the first connection electrodes CNE1 and the second interlayer insulating layer ILD2. The first passivation layer PAS1 may protect the thin-film transistors TFT. The first passivation layer PAS1 may include contact holes through which the second connection electrodes CNE2 pass or extend.

The second connection electrodes CNE2 may be disposed on the first passivation layer PAS1 The second connection electrodes CNE2 may electrically connect the first connection electrodes CNE1 to pixel electrodes AE1 through AE3 of light emitting elements ED, respectively. The second connection electrodes CNE2 may be inserted into (e.g., extend through) the contact holes formed in the first passivation layer PAS1 to contact the first connection electrodes CNE1. A first connection electrode CNE1 which contacts a second connection electrode CNE2 may form a connection electrode together with the second connection electrode CNE2.

The second passivation layer PAS2 may cover the second connection electrodes CNE2 and the first passivation layer PAS1. The second passivation layer PAS2 may include contact holes through which the pixel electrodes AE1 through AE3 of the light emitting elements ED pass.

The light emitting element layer EMIL may be disposed on the thin-film transistor layer TFTL. The light emitting element layer EML may include the light emitting elements ED, the pixel defining layer PDL, capping layers CAP, and a bank structure BNS. The light emitting elements ED may include the pixel electrodes AE1 through AE3, light emitting layers EL1 through EL3, and common electrodes CE1 through CE3, respectively.

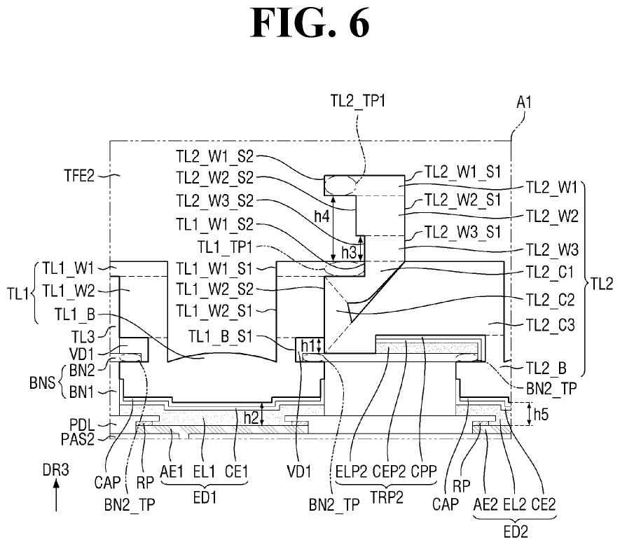

FIG. 6 is an enlarged cross-sectional view of area A1 of FIG. 5.

Referring to FIG. 6 in addition to FIG. 5, the display device 10 may include a plurality of emission areas EA1 through EA3 disposed in the display area DA. The emission areas EA1 through EA3 may include or define planar areas where light is emitted from the light emitting elements ED1 through ED3 respectively including the pixel electrodes AE1 through AE3, the light emitting layers EL1 through EL3 and the common electrodes CE1 through CE3, and passes through the color filter layer CFL in the third direction DR3. Boundaries between adjacent emission area among the emission areas EA1 through EA3 may be defined by the pixel defining layer PDL. The emission areas EA1 through EA3 may include a first emission area EA1, a second emission area EA2, and a third emission area EA3 spaced apart from each other and emitting light of the same color or different colors from each other.

In an embodiment, the first through third emission areas EA1 through EA3 may have the same planar area or planar size. For example, in the display device 10, the first emission area EA1, the second emission area EA2, and the third emission area EA3 may have the same area. However, the present disclosure is not limited thereto. In the display device 10, the first through third emission areas EA1 through EA3 may also have different areas or sizes from each other. For example, the area (e.g., the planar area) of the second emission area EA2 may be larger than the area of the first emission area EA1 and the area of the third emission area EA3, and the area of the third emission area EA3 may be larger than the area of the first emission area EA1. The intensity of light emitted from each of the emission areas EA1 through EA3 may vary according to the respective area of the emission area EA1, EA2 or EA3, and the color of an image displayed on the display screen of the display device 10 may be controlled by adjusting the area of each of the emission areas EA1 through EA3. In the embodiment of FIG. 4, the emission areas EA1 through EA3 have the same area for purposes of illustration. However, the present disclosure is not limited thereto.

In the display device 10, one first emission area EA1, one second emission area EA2, and one third emission area EA3 adjacent to each other may form one pixel group. The first to third emission areas EA1 to EA3 may be in order along the light emitting element layer EML. One pixel group may include the emission areas EA1 through EA3 emitting light of different colors to express a white gray level. However, the present disclosure is not limited thereto, and the combination of the emission areas EA1 through EA3 constituting one pixel group can be variously modified according to the arrangement of the emission areas EA1 through EA3 and the colors of light emitted from the emission areas EA1 through EA3.

A plurality of openings formed or defined in the bank structure BNS of the light emitting element layer EML are defined extended along the boundary of the bank structure BNS. That is, a solid portion (or a material portion) of the bank structure BNS may have a sidewall defining an opening, and the opening may extend around a periphery of the solid portion in the plan view. The first bank layer BN1 and the second bank layer BN2 may together provide the bank structure BNS and solid portions thereof may surround the emission areas EA1 through EA3. The areas of the bank openings of the bank structure BNS may include areas of the first through third emission areas EA1 through EA3, respectively.

The display device 10 may include a plurality of light emitting elements ED1 through ED3 disposed in different emission areas EA1 through EA3. The light emitting elements ED1 through ED3 may include a first light emitting element ED1 disposed in the first emission area EA1, a second light emitting element ED2 disposed in the second emission area EA2, and a third light emitting element ED3 disposed in the third emission area EA3.

The light emitting elements ED1 through ED3 may include the pixel electrodes AE1 through AE3, the light emitting layers EL1 through EL3, and the common electrodes CE1 through CE3, respectively.

The light emitting elements ED1 through ED3 disposed in different emission areas EA1 through EA3 may emit light of different colors from each other depending on the materials of the light emitting layers EL1 through EL3. For example, the first light emitting element ED1 disposed in the first emission area EA1 may emit red first light having a peak wavelength of about 610 nanometers (nm) to about 650 nm, the second light emitting element ED2 disposed in the second emission area EA2 may emit green second light having a peak wavelength of about 510 nm to about 550 nm, and the third light emitting element ED3 disposed in the third emission area EA3 may emit blue third light having a peak wavelength of about 440 nm to about 480 nm.

The first through third emission areas EA1 through EA3 constituting one pixel group may include the light emitting elements ED1 through ED3 emitting light of different colors from each other to express a white gray level. Alternatively, the light emitting layers EL1 through EL3 may include two or more materials emitting light of different colors, so that one light emitting layer can emit mixed light. For example, the light emitting layers EL1 through EL3 may include a red light emitting material together with a green light emitting material to emit yellow light or may include a red light emitting material together with a green light emitting material and a blue light emitting material to emit white light.

The pixel electrodes AE1 through AE3 may be disposed on the second passivation layer PAS2. The pixel electrodes AE1 through AE3 may be disposed in the emission areas EA1 through EA3, respectively. The pixel electrodes AE1 through AE3 may include a first pixel electrode AE1 disposed in the first emission area EA1, a second pixel electrode AE2 disposed in the second emission area EA2, and a third pixel electrode AE3 disposed in the third emission area EA3. The first pixel electrode AE1, the second pixel electrode AE2, and the third pixel electrode AE3 may be spaced apart from each other along the second passivation layer PAS2.

The pixel electrodes AE1 through AE3 may be respectively electrically connected to the drain electrodes DE of the thin-film transistors TFT through the first and second connection electrodes CNE1 and CNE2. The first through third pixel electrodes AE1 through AE3 may be insulated from each other by a material portion of the pixel defining layer PDL covering edges of the pixel electrodes AE1 through AE3 which are spaced apart from each other.

The pixel electrodes AE1 through AE3 may include a transparent electrode material or/and a conductive metal material. The metal material may be at least one of silver (Ag), copper (Cu), aluminum (Al), nickel (Ni), lanthanum (La), titanium (Ti), and titanium nitride (TiN). The transparent electrode material may be at least one of indium tin oxide (ITO), indium zinc oxide (IZO), and indium tin zinc oxide (ITZO). The pixel electrodes AE1 through AE3 may have a multilayer structure including the transparent electrode material and the conductive metal material.

The pixel defining layer PDL may be disposed on the second passivation layer PAS2, residual patterns RP, and the pixel electrodes AE1 through AE3. The pixel defining layer PDL may be disposed on an entirety of the second passivation layer PAS2 including covering side surfaces of the pixel electrodes AE1 through AE3 and the residual patterns RP, except for pixel openings corresponding to light emission areas at which upper surfaces of the pixel electrodes AE1 through AE3 are exposed to outside the pixel defining layer PDL. For example, at respective pixel openings, the pixel defining layer PDL may expose the first pixel electrode AE1 in the first emission area EA1, and a first light emitting layer EL1 may be directly disposed on the first pixel electrode AE1 exposed to outside the pixel defining layer PDL at a respective pixel opening.

The pixel defining layer PDL may include an inorganic insulating material. The pixel defining layer PDL may include, but is not limited to, at least one of a silicon nitride layer, a silicon oxynitride layer, a silicon oxide layer, a titanium oxide layer, an aluminum oxide layer, tantalum oxide, hafnium oxide, zinc oxide, and an amorphous silicon layer.

According to an embodiment, the pixel defining layer PDL may be disposed on the pixel electrodes AE1 through AE3, but may be spaced apart from the upper surfaces of the pixel electrodes AE1 through AE3. Within a pixel opening, for example, a portion of the pixel defining layer PDL may partially overlap the upper surfaces of the pixel electrodes AE1 through AE3 in the thickness direction DR3 of the substrate SUB, but may not directly contact the upper surfaces of the pixel electrodes AE1 through AE3, such that the residual patterns RP may be disposed between the pixel defining layer PDL and the pixel electrodes AE1 through AE3 within the pixel opening. At a region adjacent to the light emission area, a sidewall of the pixel defining layer PDL may directly contact the side surfaces of the pixel electrodes AE1 through AE3.

Side surfaces of the pixel defining layer PDL define a pixel opening while side surfaces of the bank structure BNS define a bank opening. An opening may have thickness portions (or volume portions) which are arranged along the thickness direction and correspond to various material layers (e.g., the pixel defining layer PDL, the first bank layer BN1, the second bank layer BN2, etc.) Referring to FIGS. 5 and 6, for example, the side surfaces of the pixel defining layer PDL at an upper thickness portion thereof may protrude further toward the emission areas EA1 through EA3 than side surfaces at an upper thickness portion of the bank structure BNS which is defined by the second bank layer BN2.

The residual patterns RP may be disposed on the outer edges of each of the pixel electrodes AE1 through AE3. The pixel defining layer PDL may not directly contact the upper surfaces of the pixel electrodes AE1 through AE3 due to the residual patterns RP respectively disposed therebetween within the pixel opening at a region adjacent to the light emission opening.

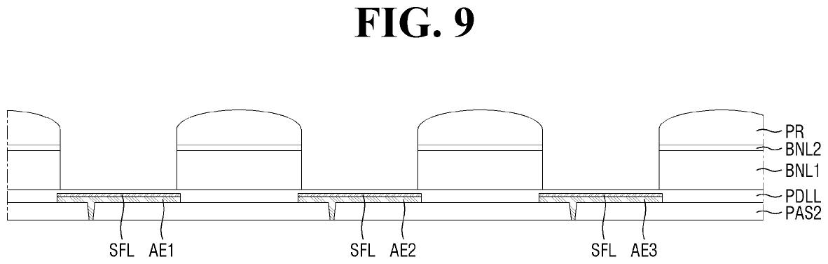

In an embodiment, the residual patterns RP may be formed or provided when sacrificial layers SFL (see FIG. 9) disposed on the pixel electrodes AE1 through AE3 are partially removed during a process of fabricating or providing the display device 10. The residual patterns RP as a remaining portion of the sacrificial layers SFL may include a metal, an oxide semiconductor, or a transparent conductive oxide (TCO). In the drawings, inner side surfaces of the residual patterns RP which face the emission areas EA1 through EA3 (e.g., are closest to the light emission areas) are recessed from inner side surfaces of the pixel defining layer PDL which are defined at the upper thickness portion thereof. However, the present disclosure is not limited thereto. The inner side surfaces of the residual patterns RP may also be aligned with the inner side surfaces of the pixel defining layer PDL or may protrude further than the inner side surfaces of the pixel defining layer PDL in a direction toward the emission areas EA1 through EA3.

The light emitting layers EL1 through EL3 may be disposed on the pixel electrodes AE1 through AE3. The light emitting layers EL1 through EL3 may be organic light emitting layers made of or including organic materials and may be formed on the pixel electrodes AE1 through AE3 such as through a deposition process. Each of the light emitting layers EL1 through EL3 may have a multilayer structure and may include a hole injecting material, a hole transporting material, a light emitting material, an electron transporting material, and/or an electron injecting material. When the thin-film transistors TFT apply a predetermined voltage to the pixel electrodes AE1 through AE3 of the light emitting elements ED1 through ED3 and the common electrodes CE1 through CE3 of the light emitting elements ED1 through ED3 receive a common voltage or a cathode voltage, holes and electrons may be injected and transported and then may be combined with each other in the light emitting layers EL1 through EL3 to emit light, respectively.

The light emitting layers EL1 through EL3 may include a first light emitting layer EL1, a second light emitting layer EL2, and a third light emitting layer EL3 disposed in different emission areas EA1 through EA3, respectively. The first light emitting layer EL1 may be disposed on the first pixel electrode AE1 in the first emission area EA1, the second light emitting layer EL2 may be disposed on the second pixel electrode AE2 in the second emission area EA2, and the third light emitting layer EL3 may be disposed on the third pixel electrode AE3 in the third emission area EA3. The light emitting layers EL1 through EL3 may emit light of different colors, or one light emitting layer EL1, EL2 or EL3 may emit a combination of the lights as a mixed light. In an embodiment, the first light emitting layer EL1 may emit red light, the second light emitting layer EL2 may emit green light, and the third light emitting layer EL3 may emit blue light. In an embodiment, the first light emitting layer EL1 may emit yellow light which is a mixture of red light and green light, and the second light emitting layer EL2 may emit blue light. In an embodiment, the first light emitting layer EL1 may emit white light which is a mixture of red light, green light, and blue light.

The light emitting layers EL1 through EL3 may extend out of respective pixel openings to be disposed on an upper surface of the pixel defining layer PDL. The light emitting layers EL1 through EL3 may be disposed in spaces or gaps defined between the pixel electrodes AE1 through AE3, and the pixel defining layer PDL, at the pixel openings. The light emitting layers EL1 through EL3 may contact the pixel defining layer PDL, the residual patterns RP, and the pixel electrodes AE1 through AE3.

The common electrodes CE1 through CE3 may be disposed on the light emitting layers EL1 through EL3. The common electrodes CE1 through CE3 may include a transparent conductive material to allow light generated by the light emitting layers EL1 through EL3 to pass therethrough. The common electrodes CE1 through CE3 may receive a common voltage or a low potential voltage. When the pixel electrodes AE1 through AE3 receive voltages corresponding to data voltages and the common electrodes CE1 through CE3 receive a low potential voltage, a potential difference may be formed between the pixel electrodes AE1 through AE3 and the common electrode CE1 through CE3. Accordingly, the light emitting layers EL1 through ED3 may emit light.

The common electrodes CE1 through CE3 may include a first common electrode CE1, a second common electrode CE2, and a third common electrode CE3 disposed in different emission areas EA1 through EA3, respectively. The first common electrode CE1 may be disposed on the first light emitting layer EL1 in the first emission area EA1, the second common electrode CE2 may be disposed on the second light emitting layer EL2 in the second emission area EA2, and the third common electrode CE3 may be disposed on the third light emitting layer EL3 in the third emission area EA3. The first through third common electrodes CE1 through CE3 may be discrete patterns which are spaced apart from each other.

The capping layers CAP may be disposed on the common electrodes CE1 through CE3. The capping layers CAP may include an organic or inorganic insulating material to cover patterns disposed on the light emitting elements ED1 through ED3. The capping layers CAP may prevent the light emitting elements ED1 through ED3 from being damaged by external air (e.g., air outside of the light emitting elements ED1 through ED3. In an embodiment, the capping layers CAP may include an organic material such as a-NPD, NPB, TPD, m-MTDATA, Alq₃, LiF, and/or CuPc or may include an inorganic material such as aluminum oxide, titanium oxide, tantalum oxide, hafnium oxide, zinc oxide, silicon oxide, silicon nitride, and/or silicon oxynitride.

The display device 10 may include the bank structure BNS disposed on the pixel defining layer PDL. The bank structure BNS may have a structure in which the bank layers BN1 and BN2 including different materials are sequentially stacked. The bank structure BNS may include a plurality of openings (e.g., bank openings) have areas including the areas of the emission areas EA1 through EA3, and solid portions which may overlap the light blocking layer BM which will be described later. The light emitting elements ED1 through ED3 of the display device 10 may overlap or be disposed in the bank openings of the bank structure BNS.

The bank structure BNS may include the first bank layer BN1 and the second bank layer BN2 sequentially stacked in a direction from the pixel defining layer PDL.

The first bank layer BN1 may be disposed on the pixel defining layer PDL and may be closer to the pixel defining layer PDL than the second bank layer BN2, along the thickness direction. Side surfaces of the first bank layer BN1 may be recessed from the side surfaces of the pixel defining layer PDL in a direction opposite to a direction toward the emission areas EA1 through EA3 (e.g., in a direction away from respective light emission areas). The side surfaces of the first bank layer BN1 may be recessed from the side surfaces of the second bank layer BN2, which will be described later, in the direction opposite to the direction toward the emission areas EA1 through EA3.

According to an embodiment, the first bank layer BN1 may include a metal material. In an embodiment, the first bank layer BN1 may include aluminum (Al) or an alloy of aluminum (Al).

In an embodiment, a thickness of the first bank layer BN1 may range from about 4000 angstroms (Å) to about 7000 Å. When the above range is satisfied, the light emitting layers EL1 through EL3 and the common electrodes CE1 through CE3 respectively separated from each other may be formed through deposition and etching processes rather than a mask process.

According to an embodiment, the common electrodes CE1 through CE3 may directly contact the side surfaces of the first bank layer BN1 which define a portion of a bank opening. The common electrodes CE1 through CE3 of different light emitting elements ED1 through ED3 may directly contact the first bank layer BN1, such as at the side surfaces thereof, and the first bank layer BN1 may include a metal material. Therefore, the common electrodes CE1 through CE3 may be electrically connected to each other through the first bank layer BN1 which is a conductive layer.

The light emitting layers EL1 through EL3 may directly contact the side surfaces of the first bank layer BN1. The area of contact between the common electrodes CE1 through CE3 and the side surfaces of the first bank layer BN1 may be larger than the area of contact between the light emitting layers EL1 through EL3 and the side surfaces of the first bank layer BN1. Here, an area of contact may be defined alone a plane or a surface of a respective element. The common electrodes CE1 through CE3 may be disposed on a larger area of the side surfaces of the first bank layer BN1 or may be disposed to a higher position along the side surfaces of the first bank layer BN1 than the light emitting layers EL1 through EL3. A higher position may be a height or distance from a reference, such as from the pixel defining layer PDL, the substrate SUB, etc. Since the common electrodes CE1 through CE3 of different light emitting elements ED1 through ED3 are electrically connected to each other through the first bank layer BN1, there may be an advantage for the common electrodes CE1 through CE3 to have a relatively large contact area with the first bank layer BN1.

The second bank layer BN2 may be disposed on the first bank layer BN1. The second bank layer BN2 may include tips BN2_TP which define inner side surfaces of the second bank layer BN2 which are closest to a light emission area and protrude from a corresponding inner side surface of the first bank layer BN1 at a same side of the light emission area. The facing inner side surfaces of the second bank layer BN2 at a same light emission area may protrude further than the corresponding inner side surfaces of the first bank layer BN1 toward the emission areas EA1 through EA3.

Since the side surfaces of the second bank layer BN2 protrude more than the side surfaces of the first bank layer BN1 in a direction toward the emission areas EA1 through EA3, an undercut structure of the bank structure BNS may be formed under each tip BN2_TP of the second bank layer BN2 together with the first bank layer BN1.

In the display device 10 according to the embodiment, since the bank structure BNS includes the tips BN2_TP (e.g., bank tips) protruding toward the emission areas EA1 through EA3, the light emitting layers EL1, EL2, and EL3 and the common electrodes CE1, CE2, and CE3 can be formed through deposition and etching processes rather than a mask process. In addition, different layers can be individually formed in different emission areas EA1 through EA3 even through a deposition process owing to the bank tips functioning to disconnect materials layers and form patterns separated from each other. For example, even if a material layer providing the light emitting layers EL1 through EL3 and material layers providing the common electrodes CE1 through CE3 of the light emitting elements ED1 through ED3 are formed by a deposition process which does not use a mask, the deposited material layers may not be connected to each other at a region between the emission areas EA1 through EA3 but may be separated from each other by the tips BN2_TP of the second bank layer BN2 with the bank structure BNS interposed between them. After a material layer for forming a specific layer is formed on an entirety of the underlying stacked structure of the display device 10, the material layer formed in unwanted areas may be removed by etching. Through this process, separated patterns of different layers can be individually formed in different emission areas EA1 through EA3. In the display device 10, it is possible to form different light emitting elements ED1 through ED3 in the emission areas EA1 through EA3, respectively, through deposition and etching processes without using a mask process, possible to omit unnecessary components from the display device 10, and possible to minimize the area of the non-display area NDA.

The side shape or cross-sectional profile of the bank structure BNS may be a structure formed in an etching process due to a difference in etch rate between the different materials from which the first bank layer BN1 and the second bank layer BN2 are respectively provided. According to an embodiment, the second bank layer BN2 may include a material having a slower etch rate than that of the first bank layer BN1, and the first bank layer BN1 may be further etched to be recessed relative to the first bank layer BN1 during the etching process to expose lower surfaces of the second bank layer BN2 at the tips BN2_TP of the second bank layer BN2 and form an undercut at each tip BN2_TP of the second bank layer BN2.

The second bank layer BN2 may include a metal material different from that of the first bank layer BN1. The metal material of the second bank layer BN2 may be a material which is removed together with the metal material of the first bank layer BN1 by dry etching but is not etched or is etched at a much slower etch rate than the first bank layer BN1 by wet etching. In an embodiment, the first bank layer BN1 may include aluminum (Al), and the second bank layer BN2 may include titanium (Ti).

The tips BN2_TP of the second bank layer BN2 may overlap the common electrodes CE1 through CE3 in a third direction DR3, where the third direction DR3 may be perpendicular to the substrate SUB and/or the plane defined by the first and second directions DR1 and DR2 crossing each other. In addition, the tips BN2_TP of the second bank layer BN2 may overlap the light emitting layers EL1 through EL3 in the bank opening, in the direction DR3. In addition, the tips BN2_TP of the second bank layer BN2 may overlap the pixel defining layer PDL in the bank opening, in the direction DR3. The common electrodes CE1 through CE3 may be formed under the lower surfaces of the tips BN2_TP of the second bank layer BN2. A portion of the common electrodes CE1 through CE3 may face the lower surface of the second bank layer BN2 at the tips BN2_TP. A maximum distance from the substrate SUB to each of the common electrodes CE1 through CE3, may be smaller than a maximum distance from the substrate SUB to the second bank layer BN2. Here, the distance may be defined along the third direction DR3, such as to be considered a vertical distance.

The display device 10 may include trace patterns TRP1 through TRP3, which are traces of a deposition process, on the bank structure BNS. The trace patterns TRP1 through TRP3 may include organic patterns ELP1 through ELP3, electrode patterns CEP1 through CEP3 and capping patterns CPP and may be disposed on the second bank layer BN2 to surround the emission areas EA1 through EA3.

In an embodiment of a method of providing the display device 10, the trace patterns TRP1 through TRP3 may be traces of material layers formed as they are separated from portions of the material layer which provide the light emitting layers EL1 through EL3, the common electrodes CE1 through CE3 and the capping layers CAP in the emission areas EA1 through EA3, by the tips BN2_TP of the bank structure BNS disconnecting the material layers. The light emitting layers EL1 through EL3, the common electrodes CE1 through CE3, and the capping layers CAP may be patterns formed in the openings, while the various material layer traces are provided outside of the openings. In addition, the organic patterns ELP1 and ELP2 as emitting layer material traces may be separated from the light emitting layers EL1 through EL3 by the tips BN2_TP of the bank structure BNS, the electrode patterns CEP1 through CEP3 as electrode material traces may be separated from the common electrodes CE1 through CE3 by the tips BN2_TP of the bank structure BNS, and the capping patterns CPP as capping material traces may be separated from the capping layers CAP by the tips BN2_TP of the bank structure BNS. The trace patterns TRP1 through TRP3 may be the result of patterning performed at regions around or adjacent to the emission areas EA1 through EA3 or around (or adjacent to) the openings.

The display device 10 according to the embodiment may include a plurality of organic patterns ELP1 through ELP3 including the same material as the light emitting layers EL1 through EL3 and disposed on the bank structure BNS. Since the light emitting layers EL1 through EL3 are formed through a process of depositing respective material layers on the entire surface of the display device 10, portions of the material layers which form the light emitting layers EL1 through EL3 may be deposited on the bank structure BNS as material traces in addition to the emission areas EA1 through EA3.

For example, the display device 10 may include the organic patterns ELP1 through ELP3 disposed on the bank structure BNS. The organic patterns ELP1 through ELP3 may include a first organic pattern ELP1, a second organic pattern ELP2, and a third organic pattern ELP3 disposed on the second bank layer BN2 of the bank structure BNS.

The first organic pattern ELP1 may include the same material as the first light emitting layer EL1 of the first light emitting element ED1. The second organic pattern ELP2 may include the same material as the second light emitting layer EL2 of the second light emitting element ED2, and the third organic pattern ELP3 may include the same material as the third light emitting layer EL3 of the third light emitting element ED3. Each of the organic patterns ELP1 through ELP3 may be formed in a process of forming the light emitting layer EL1, EL2 or EL3 including the same material as the organic pattern ELP1, ELP2 or ELP3. The organic patterns ELP1 through ELP3 may be disposed adjacent to the emission areas EA1 through EA3 in which the light emitting layers EL1 through EL3 are disposed, respectively. Here, the organic patterns ELP1 through ELP3 and the light emitting layers EL1 through EL3 may be in a same layer as each other, respectively. As being in a same layer, elements may be formed in a same process and/or include a same material as each other, elements may be respective portions of a same material layer, elements may be on a same layer by forming an interface with a same underlying or overlying layer, etc., without being limited thereto.

The display device 10 according to the embodiment may include a plurality of electrode patterns CEP1 through CEP3 including the same material as the common electrodes CE1 through CE3 and disposed on the bank structure BNS. A first electrode pattern CEP1, a second electrode pattern CEP2, and a third electrode pattern CEP3 may be directly disposed on the first organic pattern ELP1, the second organic pattern ELP2, and the third organic pattern ELP3, respectively. The arrangement relationship between the electrode patterns CEP1 through CEP3 and the organic patterns ELP1 through ELP3 may be the same as the arrangement relationship between the light emitting layers EL1 through EL3 and the common electrodes CE1 through CE3 of the light emitting elements ED1 through ED3.

The display device 10 may include the capping patterns CPP disposed on the bank structure BNS. The capping patterns CPP may be directly disposed on the first electrode pattern CEP1, the second electrode pattern CEP2, and the third electrode pattern CEP3. The arrangement relationship between the capping patterns CPP and the electrode patterns CEP1 through CEP3 may be the same as the arrangement relationship between the common electrodes CE1 through CE3 of the light emitting elements ED1 through ED3 and the capping layers CAP.

The thin-film encapsulation layer TFEL may be disposed on the light emitting elements ED1 through ED3 and the bank structure BNS, and may cover the light emitting elements ED1 through ED3 and the bank structure BNS. The thin-film encapsulation layer TFEL may include at least one inorganic layer to prevent oxygen or moisture from permeating into the light emitting element layer EML. The thin-film encapsulation layer TFEL may include at least one organic layer to protect the light emitting element layer EML from foreign substances such as dust.

In an embodiment, the thin-film encapsulation layer TFEL may include a lower inorganic encapsulation layer TFE1, the organic encapsulation layer TFE2, and the upper inorganic encapsulation layer TFE3 stacked sequentially.

Each of the lower inorganic encapsulation layer TFE1 and the upper inorganic encapsulation layer TFE3 may include at least one inorganic insulating material. The inorganic insulating material may be any one of silicon oxide, silicon nitride, and silicon oxynitride, for example, may be aluminum oxide, titanium oxide, tantalum oxide, hafnium oxide, zinc oxide, silicon oxide, silicon nitride, and/or silicon oxynitride.

The organic encapsulation layer TFE2 may include a polymer-based material. Examples of the polymer-based material may include acrylic resin, epoxy resin, polyimide, and polyethylene. For example, the organic encapsulation layer TFE2 may include acrylic resin such as polymethyl methacrylate or polyacrylic acid. The organic encapsulation layer TFE2 may be formed by curing a monomer or applying a polymer.

The lower inorganic encapsulation layer TFE1 may be disposed as patterns on the light emitting elements ED1 through ED3 and the bank structure BNS. The lower inorganic encapsulation layer TFE1 may include the first inorganic layer TL1, the second inorganic layer TL2, and the third inorganic layer TL3 disposed to correspond to different emission areas EA1 through EA3, respectively. The first inorganic layer TL1, the second inorganic layer TL2, and the third inorganic layer TL3 may include an inorganic insulating material to cover the light emitting elements ED1 through ED3, respectively. The first inorganic layer TL1, the second inorganic layer TL2, and the third inorganic layer TL3 may prevent the light emitting elements ED1 through ED3 from being damaged by external air.

Since the lower inorganic encapsulation layer TFE1 (TL1 through TL3) can be formed through chemical vapor deposition (CVD), the lower inorganic material may be formed along steps of layers on which it is deposited. For example, each of the first inorganic layer TL1, the second inorganic layer TL2, and the third inorganic layer TL3 may form a thin layer even along surfaces or profiles which are under an undercut formed by a tip BN2_TP of the bank structure BNS.

In FIGS. 5 and 6, for example, a thickness of the lower inorganic encapsulation layer TL1 through TL3 sealing the light emitting elements ED1 through ED3 along outer surfaces of the light emitting elements ED1 through ED3 is not uniform. However, the lower inorganic encapsulation layer TL1 through TL3 may be disposed with a uniform thickness along the upper, side and lower surfaces of the second bank layer BN2, the side surfaces of the first bank layer BN1, and upper surfaces of the common electrodes CE1 through CE3. Thicknesses of a layer may be taken in a direction normal to a respective surface along which the layer is disposed.

The lower inorganic encapsulation layer TFE1 may have a multilayer structure, but may also have a single-layer structure depending on area. The lower inorganic encapsulation layer TFE1 may include one or more of a silicon oxide layer, a silicon nitride layer, and a silicon oxynitride layer. Specific materials may be silicon oxide, silicon nitride, and/or silicon oxynitride. Each of the first through third inorganic layers TL1 through TL3 may include a lower insulating layer including silicon (Si) and nitrogen (N) and an upper insulating layer disposed on the lower insulating layer and including silicon (Si) and oxygen (O). The lower insulating layer may also include oxygen, but the upper insulating layer may be more oxygen-rich (O-rich) than the lower insulating layer. The upper insulating layer may also include nitrogen, but the lower insulating layer may be more nitrogen-rich (N-rich) than the upper insulating layer. That is, the oxygen content of the upper insulating layer may be greater than that of the lower insulating layer. The nitrogen content of the lower insulating layer may be greater than that of the upper insulating layer. A thickness of the lower insulating layer may be far greater than that of the upper insulating layer.

Each of the first through third inorganic layers TL1 through TL3 of the lower inorganic encapsulation layer TFE1 may have wing portions spaced apart from the upper surface of the second bank layer BN2, and a portion of another lower inorganic encapsulation layer among the first through third inorganic layers TL1 through TL3 may be disposed on and under the wing portions. Therefore, corresponding wing portions of the first through third inorganic layers TL1 through TL3 may support each other along the thickness direction. Accordingly, step coverage of the first through third inorganic layers TL1 through TL3 may be supplemented by overlapping wing portions.

The first inorganic layer TL1 may not overlap the second emission area EA2 and the third emission area EA3 and may be disposed on the first emission area EA1 and a portion of the bank structure BNS which is around or immediately adjacent to the first emission area EA1. Similarly, the second inorganic layer TL2 may not overlap the first emission area EA1 and the third emission area EA3 and may be disposed on the second emission area EA2 and the bank structure BNS around the second emission area EA2. Similarly, the third inorganic layer TL3 may not overlap the first emission area EA1 and the second emission area EA2 and may be disposed on the third emission area EA3 and the bank structure BNS around the third emission area EA3. On the bank structure BNS, at various areas adjacent to the light emission areas, the first inorganic layer TL1 and the second inorganic layer TL2 may overlap each other, the second inorganic layer TL2 and the third inorganic layer TL3 may overlap each other, and the first inorganic layer TL1 and the third inorganic layer TL3 may overlap each other.

The first inorganic layer TL1 disposed on the first light emitting element ED1 may include a body portion TL1_B, a first wing portion TL1_W1, and a second wing portion TL1_W2. The body portion TL1_B of the first inorganic layer TL1 may be disposed on the first common electrode CE1 and may include a portion surrounded by the bank structure BNS. The first wing portion TL1_W1 of the first inorganic layer TL1 may be a portion of the first inorganic layer TL1 which is farthest from the substrate SUB and/or the body portion TL1_B. The first wing portion TL1_W1 may be disposed on the second bank layer BN2, but may be spaced apart from the upper surface of the second bank layer BN2. The second wing portion TL1_W2 of the first inorganic layer TL1 may connect the body portion TL1_B of the first inorganic layer TL1 and the first wing portion TL1_W1 of the first inorganic layer TL1 to each other, but may be spaced apart from the upper surface of the second bank layer BN2. The first wing portion TL1_W1 and the second wing portion TL1_W2 of the first inorganic layer TL1 may be located above the second bank layer BN2 and may have a wing shape protruding from the body portion TL1_B1 of the first inorganic layer TL1 in the thickness direction DR3.

The first wing portion TL1_W1 of the first inorganic layer TL1 may include a first side surface TL1_W1_S1 overlapping the first light emitting layer EL1 and a second side surface TL1_W1_S2 opposite the first side surface TL1_W1_S1. The second wing portion TL1_W2 of the first inorganic layer TL1 may include a first side surface TL1_W2_S1 overlapping the first light emitting layer EL1 and a second side surface TL1_W2_S2 opposite the first side surface TL1_W2_S1. The second side surface TL1_W1_S2 of the first wing portion TL1_W1 of the first inorganic layer TL1 may protrude more than the second side surface TL1_W2_S2 of the second wing portion TL1_W2 of the first inorganic layer TL1. The first wing portion TL1_W1 of the first inorganic layer TL1 may include a tip structure TL1_TP1, and an undercut structure may be formed under the tip TL1_TP1.

The first side surface TL1_W1_S1 of the first wing portion TL1_W1 of the first inorganic layer TL1 and the first side surface TL1_W2_S1 of the second wing portion TL1_W2 of the first inorganic layer TL1 may be aligned to form a flat surface.

The body portion TL1_B of the first inorganic layer TL1 may include a first side surface TL1_B_S1 facing a side surface of the second bank layer BN2. The first side surface TL1_B_S1 of the body portion TL1_B of the first inorganic layer TL1 may overlap the first light emitting layer EL1 and may be recessed more than the second side surface TL1_W1_S2 of the first wing portion TL1_W1 of the inorganic layer TL1 and the second side surface TL1_W2_S2 of the second wing portion TL1_W2 of the first inorganic layer TL1. The first side surface TL1_B_S1 of the body portion TL1_B of the first inorganic layer TL1 may be spaced apart from or may contact the side surface of the second bank layer BN2.

A void space may exist on some areas of the second bank layer BN2. A first void space VD1 surrounded by the second wing portion TL1_W2 of the first inorganic layer TL1, the body portion TL1_B of the first inorganic layer TL1, and the second inorganic layer TL2 (or the third inorganic layer TL3) may exist. The first void space VD1 may be a space or gap formed by removal of a first trace pattern TRP1 which occupied the space. A thickness of the first void space VD1 may be defined as a first distance h1 (or first thickness) between the second bank layer BN2 and the second wing portion TL1_W2 of the first inorganic layer TL1. The first distance h1 of the first void space VD1 is equal to a second distance h2 (or second thickness) between the first pixel electrode AE1 and the body portion TL1_B of the first inorganic layer TL1, and the first distance h1 between the second bank layer BN2 and the second wing portion TL1_W2 of the first inorganic layer TL1 is equal to the second distance h2 between the first pixel electrode AE1 and the body portion TL1_B of the first inorganic layer TL1. That is, the thickness of the first void space VD1 may be the sum of thicknesses of the light emitting layer EL1 and the common electrode CE1 in the first emission area EA1. When a capping layer CAP is formed, the thickness of the first void space VD1 may be equal to the sum of the above thicknesses and a thickness of the capping layer CAP.

The body portion TL1_B of the first inorganic layer TL1 may include silicon (Si), oxygen (O), and nitrogen (N). The body portion TL1_B of the first inorganic layer TL1 may include a lower insulating layer including silicon (Si) and nitrogen (N) and an upper insulating layer disposed on the lower insulating layer and including silicon (Si) and oxygen (O). The lower insulating layer may include silicon nitride or silicon oxynitride. The upper insulating layer may include silicon oxide.

The first wing portion TL1_W1 of the first inorganic layer TL1 may include silicon (Si) and oxygen (O). The nitrogen content of the first wing portion TL1_W1 of the first inorganic layer TL1 may be very small, negligible or zero. The first wing portion TL1_W1 of the first inorganic layer TL1 may include the above-described upper insulating layer and may not include a lower insulating layer.

The second wing portion TL1_W2 of the first inorganic layer TL1 may include silicon (Si) and oxygen (O) and, optically, may further include nitrogen (N).

A thickness of the first wing portion TL1_W1 of the first inorganic layer TL1 may be smaller than a thickness of the second wing portion TL1_W2 of the first inorganic layer TL1. A thickness of the protruding tip TL1_TP1 of the first wing portion TL1_W1 of the first inorganic layer TL1 may be much smaller than the thickness of the second wing portion TL1_W2 of the first inorganic layer TL1.

The second inorganic layer TL2 disposed on the second light emitting element ED2 may include a body portion TL2_B, a first wing portion TL2_W1, a second wing portion TL2_W2, a third wing portion TL2_W3, a first connection portion TL2_C1, a second connection portion TL2_C2, and a third connection portion TL2_C3. The body portion TL2_B of the second inorganic layer TL2 may be disposed on the second common electrode CE2 and may include a portion surrounded by the bank structure BNS. The first wing portion TL2_W1 of the second inorganic layer TL2 may be a portion of the second inorganic layer TL2 which is farthest from the substrate SUB and may be disposed on the second bank layer BN2 and the first wing portion TL1_W1 of the first inorganic layer TL1. The first connection portion TL2_C1 of the second inorganic layer TL2 may be disposed between the first wing portion TL1_W1 of the first inorganic layer TL1 and the second bank layer BN2, that is, may be disposed under the tip TL1_TP1 of the first wing portion TL1_W1 of the first inorganic layer TL1. The third wing portion TL2_W3 of the second inorganic layer TL2 may protrude from the first connection portion TL2_C1 of the second inorganic layer TL2 in the thickness direction DR3 of the substrate SUB. The second wing portion TL2_W2 of the second inorganic layer TL2 may connect the third wing portion TL2_W3 of the second inorganic layer TL2 and the first wing portion TL2_W1 of the second inorganic layer TL2. The second connection portion TL2_C2 of the second inorganic layer TL2 may be connected to the first connection portion TL2_C1 of the second inorganic layer TL2 and may be disposed on the second side surface TL1_W2_S2 of the second wing portion TL1_W2 of the first inorganic layer TL1. The third connection portion TL2_C3 of the second inorganic layer TL2 may connect the second connection portion TL2_C2 of the second inorganic layer TL2 and the body portion TL2_B of the second inorganic layer TL2 and may be disposed on the second bank layer BN2 and a second trace pattern TRP2.

The first inorganic layer TL1 and the second inorganic layer TL2 may overlap each other in the thickness direction DR3 of the substrate SUB on the bank structure BNS between the first emission area EA1 and the second emission area EA2. The first wing portion TL1_W1 of the first inorganic layer TL1 and the first wing portion TL2_W1 of the second inorganic layer TL2 may overlap each other. The tip TL1_TP1 of the first inorganic layer TL1 and a tip TL2_TP1 of the second inorganic layer TL2 may overlap each other. The tip TL1_TP1 of the first inorganic layer TL1 may not overlap the second trace pattern TRP2. The second trace pattern TRP2 is disposed on the bank structure BNS between the first emission area EA1 and the second emission area EA2, but is not disposed on the bank structure BNS between the second emission area EA2 and the third emission area EA3. A second void space VD2 from which the second trace pattern TRP2 has been removed may exist on the bank structure BNS between the second emission area EA2 and the third emission area EA3.

The first wing portion TL2_W1 of the second inorganic layer TL2 and the second wing portion TL2_W2 of the second inorganic layer TL2 may be spaced apart from an upper surface of the first wing portion TL1_W1 of the first inorganic layer TL1. A space between the first wing portion TL2_W1 of the second inorganic layer TL2 and the first wing portion TL1_W1 of the first inorganic layer TL1 may be filled with the organic encapsulation layer TFE2.

The first wing portion TL2_W1 of the second inorganic layer TL2 may include a first side surface TL2_W1_S1 adjacent to the second light emitting layer EL2 and a second side surface TL2_W1_S2 opposite the first side surface TL2_W1_S1. The second wing portion TL2_W2 of the second inorganic layer TL2 may include a first side surface TL2_W2_S1 adjacent to the second light emitting layer EL2 and a second side surface TL2_W2_S2 opposite the first side surface TL2_W2_S1. The third wing portion TL2_W3 of the second inorganic layer TL1 may include a first side surface TL2_W3_S1 adjacent to the second light emitting layer EL2 and a second side surface TL2_W3_S2 opposite the first side surface TL2_W3_S1.

The second side surface TL2_W1_S2 of the first wing portion TL2_W1 of the second inorganic layer TL2 may protrude more than the second side surface TL2_W2_S2 of the second wing portion TL2_W2 of the second inorganic layer TL2. The first wing portion TL2_W1 of the second inorganic layer TL2 may include a tip structure TL2_TP1, and an undercut structure may be formed under the tip TL2_TPL. The second side surface TL2_W1_S2 of the first wing portion TL2_W1 of the second inorganic layer TL2 may protrude more than the second side surface TL2_W3_S2 of the third wing portion TL2_W3 of the second inorganic layer TL2.

In FIG. 6, the second side surface TL2_W2_S2 of the second wing portion TL2_W2 of the second inorganic layer TL2 protrudes more than the second side surface TL2_W3_S2 of the third wing portion TL2_W3 of the second inorganic layer TL2. However, the present disclosure is not limited thereto. The second side surface TL2_W2_S2 of the second wing portion TL2_W2 of the second inorganic layer TL2 may also be aligned with the second side surface TL2_W3_S2 of the third wing portion TL2_W3 of the second inorganic layer TL2 or may be recessed more than the second side surface TL2_W3_S2 of the third wing portion TL2_W3 of the second inorganic layer TL2.

The first side surface TL2_W1_S1 of the first wing portion TL2_W1 of the second inorganic layer TL2, the first side surface TL2_W2_S1 of the second wing portion TL2_W2 of the second inorganic layer TL2, and the first side surface TL2_W3_S1 of the third wing portion TL2_W3 of the second inorganic layer TL2 may be aligned to form a flat surface. That is, the various side surfaces may be coplanar with each other to form the flat surface.

The first connection portion TL2_C1 of the second inorganic layer TL2 may be adjacent to the first wing portion TL1_W1 of the first inorganic layer TL1. The first connection portion TL2_C1 of the second inorganic layer TL2 may contact a lower surface of the first wing portion TL1_W1 of the first inorganic layer TL1 to support the tip TL1_TP1 of the first inorganic layer TL1 and prevent permeation of air from the outside.

The second connection portion TL2_C2 of the second inorganic layer TL2 may be adjacent to the second wing portion TL1_W2 of the first inorganic layer TL1. The second connection portion TL2_C2 of the second inorganic layer TL2 may contact the second side surface TL1_W2_S2 of the second wing portion TL1_W2 of the first inorganic layer TL1 to block a moisture permeation path.

The third connection portion TL2_C3 of the second inorganic layer TL2 may be disposed on the second bank layer BN2 and the second trace pattern TRP2. A portion of a lower surface of the third connection portion TL2_C3 of the second inorganic layer TL2 may contact the second bank layer BN2, and another portion may contact the second trace pattern TRP2. That is, a portion of the upper surface of the second bank layer BN2 may contact the third connection portion TL2_C3 of the second inorganic layer TL2, and another portion of the upper surface of the second bank layer BN2 may contact the second organic pattern ELP2.

A fine void space may exist between the first through third connection portions TL2_C1, TL2_C2 and TL2_C3 of the second inorganic layer TL2. That is, the first through third connection portions TL2_C1, TL2_C2 and TL2_C3 may together define a void. A wider portion of the void may be defined at the second connection portion TL2_C2, and a width (or volume) of the void may decrease in a direction away from the second connection portion TL2_C2. The first connection portion TL2_C1 of the second inorganic layer TL2 and the third connection portion TL2_C3 of the second inorganic layer TL2 may be bonded to each other at a location spaced apart from the second connection portion TL2_C2, thereby securing structural stability of the second inorganic layer TL2.

The body portion TL2_B of the second inorganic layer TL2 and the third connection portion TL2_C3 of the second inorganic layer TL2 may include silicon (Si), oxygen (O), and nitrogen (N). The body portion TL2_B of the second inorganic layer TL2 and the third connection portion TL2_C3 of the second inorganic layer TL2 may include a lower insulating layer including silicon (Si) and nitrogen (N) and an upper insulating layer disposed on the lower insulating layer and including silicon (Si) and oxygen (O). The lower insulating layer may include silicon nitride or silicon oxynitride. The upper insulating layer may include silicon oxide.

The first wing portion TL2_W1 of the second inorganic layer TL2 may include silicon (Si) and oxygen (O). The nitrogen content of the first wing portion TL2_W1 of the second inorganic layer TL2 may be very small or zero. The first wing portion TL2_W1 of the second inorganic layer TL2 may include the above-described upper insulating layer and may not include a lower insulating layer.

The second wing portion TL2_W2 of the second inorganic layer TL2 and the third wing portion TL2_W3 of the second inorganic layer TL2 may include silicon (Si) and oxygen (O) and, optionally, may further include nitrogen (N).

The first and second connection portions TL2_C1 and TL2_C2 of the second inorganic layer TL2 may include silicon (Si) and nitrogen (N). The oxygen content of the first and second connection portions TL2_C1 and TL2_C2 of the second inorganic layer TL2 may be very small or zero. The first and second connection portions TL2_C1 and TL2_C2 of the second inorganic layer TL2 may include the above-described lower insulating layer and may not include an upper insulating layer.

A thickness of the first wing portion TL2_W1 of the second inorganic layer TL2 may be smaller than a thickness of the second wing portion TL2_W2 of the second inorganic layer TL2. A thickness of the protruding tip TL2_TP1 of the first wing portion TL2_W1 of the second inorganic layer TL2 may be much smaller than the thickness of the second wing portion TL2_W2 of the second inorganic layer TL2.

A third thickness h3 (or third thickness) of the third wing portion TL2_W3 of the second inorganic layer TL2 may be equal to a fifth distance h5 (or fifth thickness) between the second pixel electrode AE2 and the body portion TL2_B of the second inorganic layer TL2. The fifth distance h5 between the second pixel electrode AE2 and the body portion TL2_B of the second inorganic layer TL2 may be the sum of thicknesses of the light emitting layer EL2 and the common electrode CE2 in the second emission area EA2. When a capping layer CAP is formed, the fifth distance h5 may be the sum of the above thicknesses and a thickness of the capping layer CAP. A fourth distance h4 (or fourth thickness) between the first wing portion TL1_W1 of the first inorganic layer TL1 and the first wing portion TL2_W1 of the second inorganic layer TL2 may be greater than the fifth distance h5 between the second pixel electrode AE2 and the body portion TL2_B of the second inorganic layer TL2.

Referring to FIG. 5, a tip structure of the second inorganic layer TL2 may also be formed as in FIG. 6 on the second bank layer BN2 between the second emission area EA2 and the third emission area EA3, and the third inorganic layer TL3 may be disposed on and under the tip structure. A tip structure of the first inorganic layer TL1 may be formed on the second bank layer BN2 between the third emission area EA3 and the first emission area EA1, and the third inorganic layer TL3 may be disposed on and under the tip structure.

The organic encapsulation layer TFE2 is disposed on the lower inorganic encapsulation layer TL1 through TL3. Portions of the organic encapsulation layer TFE2 may be disposed between the first wing portions TL1_W1, TL2_W1 and TL3_W1 of the first through third inorganic layers TL1 through TL3. The organic encapsulation layer TFE2 may not directly contact the second bank layer BN2 between the emission areas EA1 through EA3.

The upper inorganic encapsulation layer TFE3 may be disposed on the organic encapsulation layer TFE2. The upper inorganic encapsulation layer TFE3 may include aluminum oxide, titanium oxide, tantalum oxide, hafnium oxide, zinc oxide, silicon oxide, silicon nitride, and/or silicon oxynitride.

Patterns within the light blocking layer BM may be disposed on the thin-film encapsulation layer TFEL. The light blocking layer BM may include (or define) a plurality of holes OPT1 through OPT3 (e.g., light blocking layer openings) disposed to respectively overlap the emission areas EA1 through EA3. For example, a first hole OPT1 may overlap the first emission area EA1. A second hole OPT2 may overlap the second emission area EA2, and a third hole OPT3 may overlap the third emission area EA3. The areas or sizes of the holes OPT1 through OPT3 may be larger than the areas or sizes of the emission areas EA1 through EA3, respectively. Since the holes OPT1 through OPT3 of the light blocking layer BM are formed to be larger than the emission areas EA1 through EA3, light emitted from the emission areas EA1 through EA3 can be seen from outside the display device 10 such as by a user, not only from the front but also from the side of the display device 10.

The light blocking layer BM may include a light absorbing material. For example, the light blocking layer BM may include an inorganic black pigment or an organic black pigment. The inorganic black pigment may be carbon black, and the organic black pigment may include at least one of lactam black, perylene black, and aniline black. However, the present disclosure is not limited thereto. The light blocking layer BM may prevent color mixing by preventing intrusion of visible light between the first through third emission areas EA1 through EA3, thereby improving a color gamut of the display device 10.

The display device 10 may include a plurality of color filters CF1 through CF3 disposed on the emission areas EA1 through EA3. The color filters CF1 through CF3 may be disposed to correspond to the emission areas EA1 through EA3, respectively. For example, the color filters CF1 through CF3 may be disposed on the light blocking layer BM including the holes OPT1 through OPT3 corresponding to the emission areas EA1 through EA3. The holes OPT1 through OPT3 of the light blocking layer BM may be formed to overlap the emission areas EA1 through EA3 or the openings of the bank structure BNS and may form light output areas through which light emitted from the emission areas EA1 through EA3 is output to outside the display device 10. The color filters CF1 through CF3 may have a larger area than the holes OPT1 through OPT3 of the light blocking layer BM, respectively. The color filters CF1 through CF3 may completely cover the light output areas formed by the holes OPT1 through OPT3, respectively.

The color filters CF1 through CF3 may include a first color filter CF1, a second color filter CF2, and a third color filter CF3 disposed to correspond to different emission areas EA1 through EA3, respectively. Each of the color filters CF1 through CF3 may include a colorant such as a dye or pigment which absorbs light in wavelength bands other than light in a specific wavelength band and may be disposed to correspond to the color of light emitted from one of the emission areas EA1 through EA3. For example, the first color filter CF1 may be a red color filter which overlaps the first emission area EA1 and transmits only red first light. The second color filter CF2 may be a green color filter which overlaps the second emission area EA2 and transmits only green second light, and the third color filter CF3 may be a blue color filter which overlaps the third emission area EA3 and transmits only blue third light.

Each of the color filters CF1 through CF3 may be spaced apart from other adjacent color filters CF1 through CF3 on the light blocking layer BM. The color filters CF1 through CF3 may cover the holes OPT1 through OPT3 of the light blocking layer BM and may have a larger area than the holes OPT1 through OPT3, respectively. However, each of the color filters CF1 through CF3 may have an area which allows it to be spaced apart from other color filters CF1 through CF3 on the light blocking layer BM. However, the present disclosure is not limited thereto. Each of the color filters CF1 through CF3 may also partially overlap adjacent color filters CF1 through CF3. In this case, portions of the different color filters CF1 through CF3 which do not overlap the emission areas EA1 through EA3 may overlap each other on the light blocking layer BM which will be described later. Since the color filters CF1 through CF3 overlap each other in the display device 10, the intensity of reflected light due to external light can be reduced. Further, the color of reflected light due to external light can be controlled by adjusting the arrangement, shapes, and areas of the color filters CF1 through CF3 in plan view.

The overcoat layer OC may be disposed on the color filters CF1 through CF3 to planarize upper ends of the color filters CF1 through CF3. The overcoat layer OC may be a colorless light-transmitting layer which does not have a color in a visible light band. For example, the overcoat layer OC may include a colorless light-transmitting organic material such as acrylic resin.

A process of fabricating the display device 10 according to the embodiment will now be described with reference to other drawings.

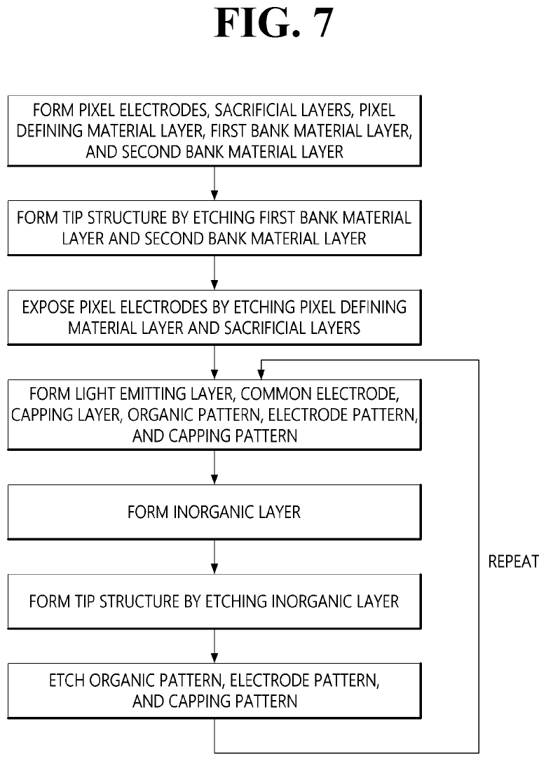

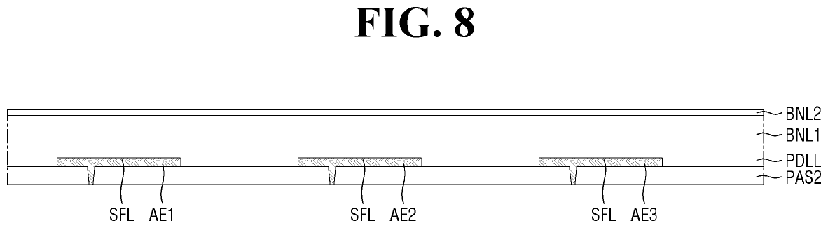

FIG. 7 is a flowchart illustrating a process of fabricating (or providing) a display device 10 according to an embodiment. FIGS. 8 through 20 are detailed cross-sectional views sequentially illustrating processes in a method of providing the display device 10 according to the embodiment.

FIGS. 8 through 20 schematically illustrate a process of forming a bank structure BNS and light emitting elements ED within a light emitting element layer EML of a display device 10, and a thin-film encapsulation layer TFEL on the light emitting layer EML. In the following description of the process of fabricating the display device 10, the formation process of each layer will not be described, and the formation order of each layer will be described.

Referring to FIG. 8, a plurality of pixel electrodes AE1 through AE3 spaced apart from each other, sacrificial layers SFL of a preliminary sacrificial layer which respectively correspond to the pixel electrodes AE1 through AE3, a pixel defining material layer PDLL as a preliminary pixel defining layer, and a plurality of bank material layers BNL1 and BNL2 as preliminary bank layers are formed (or provided) on an entirety of a second passivation layer PAS2 of an encapsulation layer.

Although not illustrated in the drawing, a thin-film transistor layer TFTL as a circuit layer (or pixel circuit layer) may be disposed on a substrate SUB. The structure of the thin-film transistor layer TFTL is the same as that described above with reference to FIG. 5, and thus a detailed description thereof will be omitted.

Referring to FIG. 9, photoresists PR are formed on the second bank material layer BNL2 to correspond to areas between adjacent pixel electrodes, and a first etching process is performed using the photoresists PR as a mask to partially etch the first and second bank material layers BNL1 and BNL2. Holes may be formed in the preliminary bank layers, through the first etching process. The photoresists PR may be spaced apart from each other on (or along) the second bank material layer BNL2 and may be disposed to expose areas of the preliminary pixel defining layer which respectively overlap the pixel electrodes AE1 through AE3.

In an embodiment, the first etching process may be performed as anisotropic dry etching. The holes or openings may be formed in the areas overlapping the pixel electrodes AE1 through AE3. The holes may form openings of the bank structure BNS which are between solid (material) portions of the bank structure BNS.

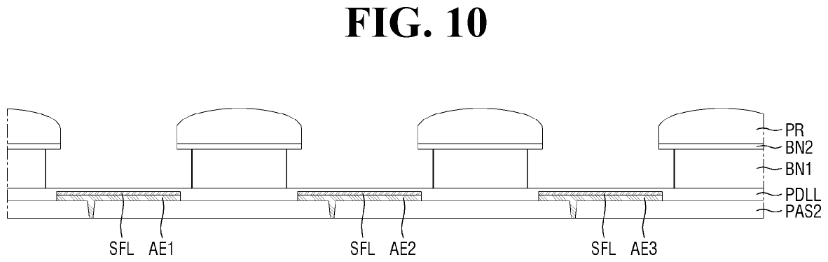

Referring to FIG. 10, an undercut structure of a first bank layer BN1 may be formed through a second etching process. The first bank material layer BNL1 may be etched faster than the second bank material layer BNL2 in the second etching process, and side surfaces of a second bank layer BN2 which define an upper portion of bank openings corresponding to the various pixel electrodes, may be formed to protrude further than side surfaces of the first bank layer BN1 which define an upper portion of the bank openings. The side surfaces of the second bank layer BN2 may protrude more than the side surfaces of the first bank layer BN1 in a direction toward the bank holes, to form tips BN2_TP of the bank structure BNS. An undercut may be formed under each tip BN2_TP, by a lower surface of the second bank layer BN2 which exposed to the bank hole, together with a corresponding side surface of the first bank layer BN1.

In an embodiment, the second etching process may be isotropic wet etching. The second etching process may use an alkali-based etchant. The bank structure BNS in a completed form of the first and second bank layers BN1 and BN2 may be obtained through the second etching process.

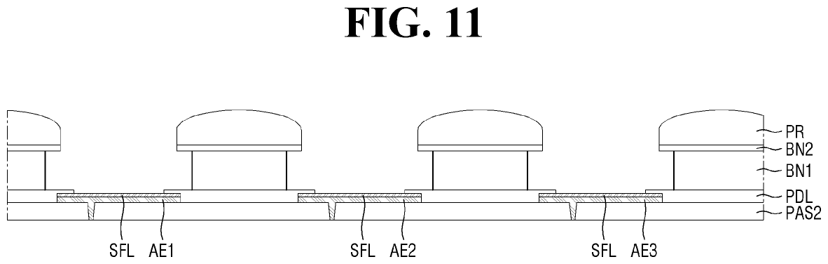

As illustrated in FIG. 11, a portion of the pixel defining material layer PDLL may be removed at areas corresponding to the various pixel electrodes, through a third etching process. The third etching process may include a dry etching operation for removing the portions of pixel defining material layer PDLL. Here, the sacrificial layers SFL which are between the preliminary pixel defining layer and the various pixel electrodes, may protect the pixel electrodes AE1 through AE3 from plasma in the dry etching operation. Here, exposed areas of the preliminary sacrificial layer are exposed to outside the preliminary pixel defining layer, at the bank openings.

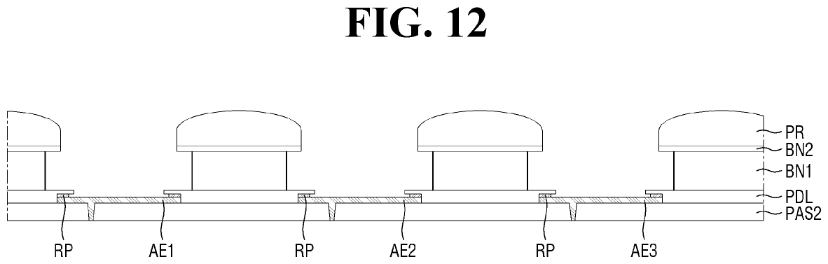

As illustrated in FIG. 12, a fourth etching process for partially removing the exposed portions of the sacrificial layers SFL may be performed to form residual patterns RP. The fourth etching process may include a wet etching operation, and portions of the sacrificial layers SFL which are exposed to the bank holes and portions of the sacrificial layers SFL which are disposed between extended portions of the pixel defining layer PDL and the pixel electrodes AE1 through AE3, respectively, may be removed. However, the sacrificial layers SFL may not be completely removed at an area closest to an innermost sidewall of the pixel defining layer PDL. The remaining portion of the sacrificial layers SFL may remain to provide the residual patterns RP between the extended portions of the pixel defining layer PDL and the pixel electrodes AE1 through AE3, respectively. The pixel electrodes AE1 through AE3 may be exposed to the bank openings, through the fourth etching process. Here, the extended portions of the pixel defining layer PDL and the residual patterns RP may form a stepped structure at an upper portion of the pixel openings corresponding to the light emission areas.

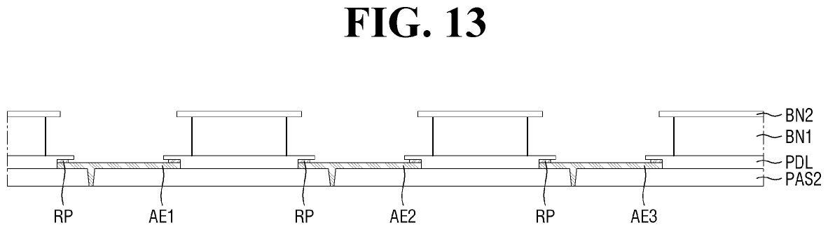

As illustrated in FIG. 13, the photoresists PR are removed. Here, exposed areas of the various pixel electrodes are exposed to outside the pixel defining layer PDL and the residual pattern layer, at the bank openings.

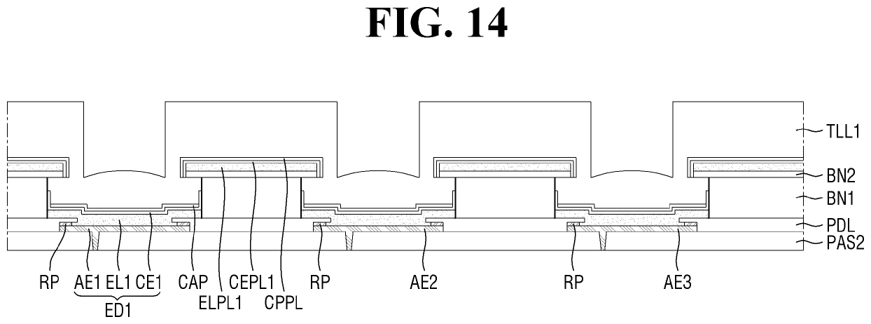

As illustrated in FIG. 14, a first light emitting layer EL1, a first common electrode CE1, and a capping layer CAP are deposited at first patterns on the first pixel electrode AE1, within the bank opening of a first emission area EA1, to form a first light emitting element ED1. Here, since respective preliminary material layers for forming the first light emitting layer EL1, the first common electrode CE1, and the capping layer CAP are formed on the entire surface of the substrate SUB, a first light emitting material layer ELPL1, a first electrode material layer CEPL1, and a capping material layer CPPL may also be formed as second patterns of the respective preliminary material layers on the second bank layer BN2.

In providing of the preliminary light emitting layer, a first pattern as the first light emitting layer EL1 and a second pattern as the first light emitting material layer ELPL1 may be separated (or disconnected) from each other by the tips BN2_TP of the second bank layer BN2. Similarly, in providing of the preliminary electrode layer, a first pattern as the first common electrode CE1 and a second pattern as the first electrode material layer CEPL1 may be separated from each other by the tips BN2_TP of the second bank layer BN2, and in providing of the preliminary capping layer, a first pattern as the capping layer CAP and a second pattern as the capping material layer CPPL may be separated from each other by the tips BN2_TP of the second bank layer BN2. The first light emitting material layer ELPL1 may be formed on the second bank layer BN2 at the same time as when the first light emitting layer EL1 is formed on the first pixel electrode AE1. The first electrode material layer CEPL1 may be formed on the first light emitting material layer ELPL1 at the same time as when the first common electrode CE1 is formed on the first light emitting layer EL1.

The first light emitting layer EL1 and the first common electrode CE1 may be formed through deposition processes. In the bank openings, materials may not be smoothly deposited due to the tips BN2_TP of the second bank layer BN2. However, since materials of the first light emitting layer EL1 and the first common electrode CE1 are deposited in a direction inclined to an upper surface of the substrate SUB rather than in a direction perpendicular to the upper surface of the substrate SUB, they may be deposited even in areas covered by the tips BN2_TP of the second bank layer BN2. That is, the preliminary material layer of the first light emitting layer EL1 and the first common electrode CE1 may be deposited on side surfaces under the tips BN2_TP of the second bank layer BN2.

A deposition process for forming the common electrodes CE1 through CE3 may be performed at an angle relatively closer to a horizontal direction than a deposition process for forming the light emitting layers EL1 through EL3. Accordingly, the common electrodes CE1 through CE3 may contact the side surfaces of the first bank layer BN1 over a larger area than an area covered by the light emitting layers EL1 through EL3, such as by the respective common electrodes extending further up the side surfaces of the first bank layer BN1. Alternatively, the common electrodes CE1 through CE3 may be deposited to a higher position on the side surfaces of the first bank layer BN1 than the light emitting layers EL1 through EL3. The different common electrodes CE1 through CE3 may be electrically connected to each other by contacting the first bank layer BN1 having high conductivity.

Referring to FIG. 14, the first trace pattern TRP1 may include organic pattern ELPL1 (as a preliminary form of an organic pattern ELP1), electrode pattern CEPL1 (as a preliminary form of an electrode pattern CEP1) and a capping pattern material layer CPPL (as a preliminary form of a capping pattern CPP) on the second bank layer BN2, which are adjacent to and surround the bank openings respectively corresponding to the emission areas EA1 through EA3. Some or all of the layers within the first trace pattern TRP1 may be removed in a subsequent process.

A first inorganic material layer TLL1 as a previous inorganic layer is formed to cover the first light emitting element ED1 and the capping layer CAP. The first inorganic material layer TLL1 may be formed to completely cover outer surfaces of the first light emitting element ED1, the bank layers BN1 and BN2, the capping layer CAP, the first light emitting material layer ELPL1, the first electrode material layer CEPL1, and the capping material layer CPPL without any broken or disconnected portions. Specifically, the first inorganic material layer TLL1 is formed on an upper surface of the first common electrode CE1, an upper surface of the capping layer CAP, the side surfaces of the first bank layer BN1, lower and upper surfaces of the second bank layer BN2, and upper surface of the electrode material layer CEPL1 and the capping material layer CPPL.

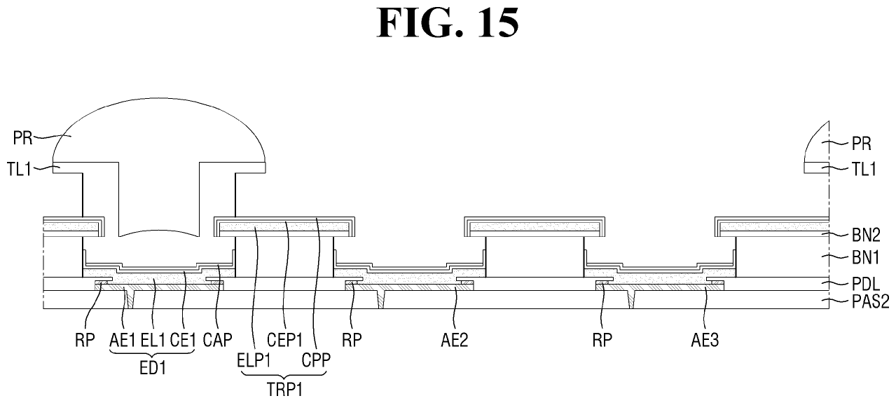

Referring to FIG. 15, a fifth etching process for partially removing portions of the first inorganic material layer TLL1 is performed to expose portions the capping material layer CPPL to outside the preliminary inorganic layer. That is, the first trace patterns TRP1 are exposed to outside the etched inorganic material layer. In an embodiment, the fifth etching process may include isotropic dry etching. A mask pattern PR may be formed on the first inorganic material layer TLL1, at a location overlapping the first pixel electrode AE1. The first inorganic material layer TLL1 not covered by the mask pattern PR and a portion of the first inorganic material layer TLL1 which is covered by the mask pattern PR may be removed. Here, an entirety of the first inorganic material layer TLL1 except for a portion corresponding to the bank opening and a portion which is adjacent to the bank opening may be removed. Removal of the portions of the first inorganic material layer TLL1 expose the first trace patterns TRP1 to outside the first inorganic material layer TLL1.

Silicon nitride or silicon oxynitride of the first inorganic material layer TLL1 covered by the mask pattern PR and surrounding the bank opening, may be removed to form protruding side surfaces of the first inorganic material layer TLL1. That is, a lower thickness portion of the first inorganic material layer TLL1 may be selectively removed. First and second wing portions TL1_W1 and TL1_W2 of a first inorganic layer TL1 may be obtained through the fifth etching process. The first inorganic material layer TLL1 is removed from areas overlapping a second emission area EA2 and a third emission area EA3 and respective sedge areas surrounding these light emission areas.

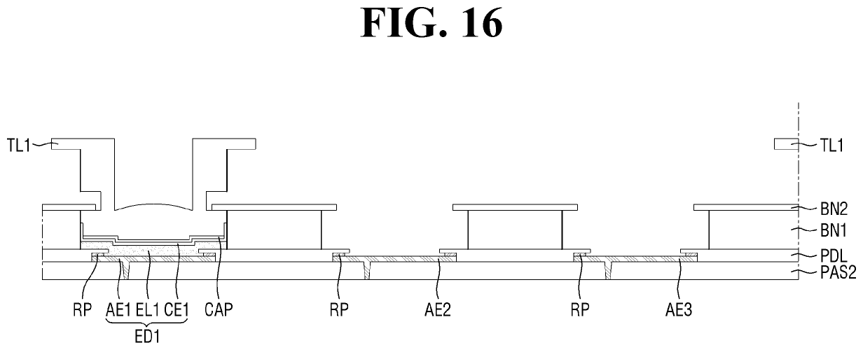

Next, referring to FIG. 16, a sixth etching process for removing the first light emitting material layer ELPL1, the first electrode material layer CEPL1 and the capping pattern material layer CPPL is performed to expose the second bank layer BN2 to outside the first inorganic material layer TLL1. In an embodiment, the sixth etching process may be an isotropic wet etching operation. Not only the first electrode material layer CEPL1, the first light emitting material layer ELPL1 and the capping pattern material layer CPPL of the first trace pattern TRP1 which are disposed on the second bank layer BN2, but also the first light emitting material layer ELPL1, the first electrode material layer CEPL1 and the capping pattern material layer CPPL of the second and third emission areas EA2 and EA3 not covered by the first inorganic material layer TLL1 may be removed. Therefore, at the first emission area EA1, the first light emitting material layer ELPL1, the first electrode material layer CEPL1 and the capping pattern material layer CPPL which are disposed between the second wing portions TL1_W2 of the first inorganic layer TL1 and the second bank layer BN2 may also be removed. An entirety of the first trace pattern TRP1 may be completely removed and no portion of the first trace pattern TRP1 may remain in a final form of the display device 10. Referring back to FIGS. 5 and 6, for example, no portion of the previously-formed first trace pattern TRP1 remains along the pixel circuit layer.

Removal of portions of the first light emitting material layer ELPL1, the first electrode material layer CEPL1 and the capping pattern material layer CPPL of the first trace pattern TRP1 which are disposed between the second wing portions TL1_W2 of the first inorganic layer TL1 and the second bank layer BN2 provide undercut structures of the first inorganic layer TL1 at the first emission area EA1. The undercut structures may define a first void space VD1. The emission area structure including patterns of TL1 through AE1 at the first emission area EA1 may be a first (or previous) emission area structure.

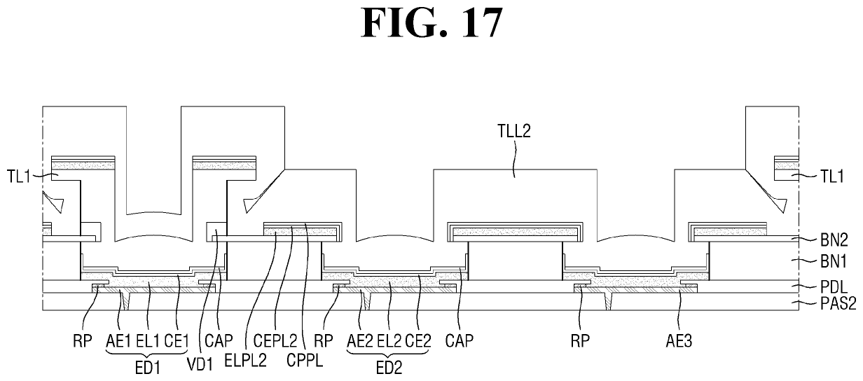

As illustrated in FIG. 17, a second light emitting layer EL2, a second common electrode CE2 and a capping layer CAP are deposited on a second pixel electrode AE2 to form a second light emitting element ED2. Then, a second inorganic material layer TLL2 as a subsequent inorganic layer is formed to cover the second light emitting element ED2 and the capping layer CAP. In this process, material layers are deposited on the entire surface of the substrate SUB as in FIG. 14, including the previous emission area structure. However, the materials are distorted or broken by tips TL1_TP1 of the first inorganic layer TL1 and the tips BN2_TP of the second bank layer BN2 into upper and lower layers. A second organic pattern material layer ELPL2, a second electrode pattern material layer CEPL2, and a capping pattern material layer CPPL may be disposed on the second bank layer BN2 and the first wing portions TL_W1 of the first inorganic layer TL1.

The second inorganic material layer TLL2 is formed to cover the second light emitting element ED2 and the capping layer CAP. The second inorganic material layer TLL2 may also be formed on lower surfaces of the tips TL1_TP1 of the first inorganic layer TL1 and may be formed to completely cover the second bank layer BN2, the capping layer CAP, the capping material layer CPPL, and upper and side surfaces of the first inorganic layer TL1 without any broken portions. However, spaces between the second wing portions TL1_W2 of the first inorganic layer TL1 and the upper surface of the second bank layer BN2 may not be completely filled with the second inorganic material layer TLL2. Here, the subsequent inorganic layer may bend or fold onto itself at the first void space VD1, to cover or block an inlet to the first void space VD1.

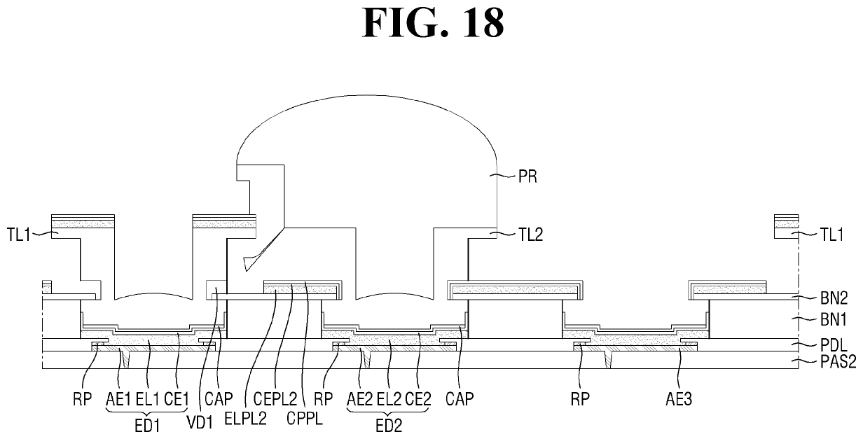

As illustrated in FIG. 18, the second inorganic material layer TLL2 may be partially removed to form a second inorganic layer TL2 overlapping the second emission area EA2 and edges which are around the second emission area EA2. This process may be performed similarly to the dry etching operation for removing the first inorganic material layer TLL1 in FIG. 15.

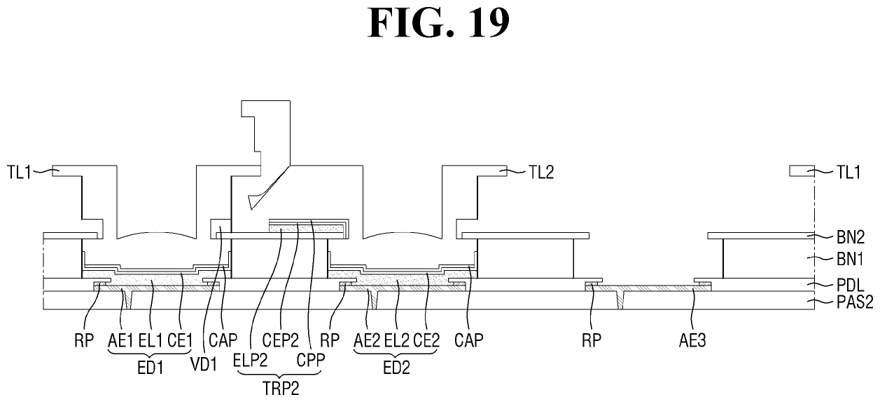

Next, as illustrated in FIG. 19, a second electrode material layer CEPL2 a second light emitting material layer ELPL2 and a capping material layer CPPL of a second trace pattern TRP2 may be removed except for an area between the previous emission area structure (TL1 through AE1) and the current emission area structure (TL2 through AE2). This process may be performed similarly to that of FIG. 16, but portions of a second trace pattern TRP2 which are disposed between a first emission area EA1 and the second emission area EA2 and surrounded by the second inorganic layer TL2 is not removed.

Removal of portions of the second light emitting material layer ELPL2, the second electrode material layer CEPL2 and the capping pattern material layer CPPL of the second trace pattern TRP2 in a preliminary form, which are disposed between a right-side wing portion of the second inorganic layer TL2 and the second bank layer BN2 provide undercut structures of the second inorganic layer TL2 at the right side of the second emission area EA2. The undercut structures may define a second void space VD2. Here, the second inorganic layer TL2 as another subsequent inorganic layer may bend or fold onto itself at the second void space VD2, to cover or block an inlet to the second void space VD2. The emission area structure including patterns of TL2 through AE2 at the second emission area EA2 may be a second (or subsequent) emission area structure.

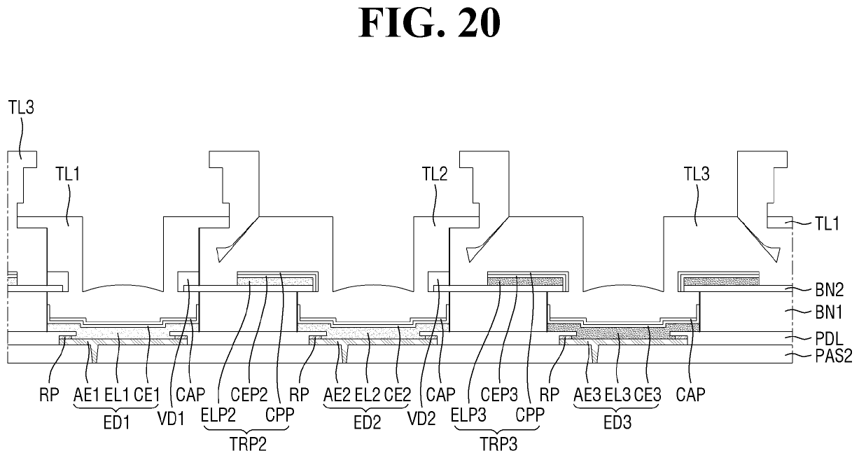

To form the third emission area structure, processes similar to the processes of FIGS. 17 through 19 may be performed to form a third light emitting element ED3 and a third inorganic layer TL3 on the third emission area EA3 as illustrated in FIG. 20. Here, a third electrode material layer a third light emitting material layer and a capping material layer CPPL of a third trace pattern TRP3 may be removed except for areas between the previous emission area structure (TL2 through AE2) and the current emission area structure (TL3 through AE3) and between the previous emission area structure (TL1 through AE1) and the current emission area structure (TL3 through AE3). That is, portions of the third trace pattern TRP3 may remain at opposing sides of the third emission area EA3, while portions of the second trace pattern TRP2 remain at only one side of the second emission area EA2 and no portion of the first trace pattern TRP1 remain at a side of the first emission area EA1.

Building on the stacked structure in FIG. 20 and referring back to FIGS. 5 and 6, although not illustrated in the drawings, an organic encapsulation layer TFE2 and an upper inorganic encapsulation layer TFE3 of the thin-film encapsulation layer TFEL, a light blocking layer BM, a color filter layer CFL, and an overcoat layer OC are formed on the light emitting elements ED1 through ED3 and the bank structure BNS of the underlying stacked structure to produce the display device 10. The structures of the thin-film encapsulation layer TFEL, the light blocking layer BM, the color filter layer CFL, and the overcoat layer OC are the same as those described above, and thus a detailed description thereof will be omitted.

In a display device 10 and a method of providing the same according to an embodiment, a previously-formed lower inorganic encapsulation layer may have a wing portion on a second bank layer BN2, and a subsequently-formed adjacent lower inorganic encapsulation layer may cover the top and bottom of the previously-formed wing portion. Since sealing between the lower inorganic encapsulation layer at the previously-formed and the subsequently-formed wing portions thereof, and a light emitting element is excellent, reliability of the display device 10 can be improved.

Referring to FIGS. 5 and 6, for example, the display device 10 includes a pixel defining layer PDL on the substrate SUB and in which a first pixel opening and a second pixel opening (e.g., at EA1 and EA2) are defined respectively exposing the first pixel electrode AE1 and the second pixel electrode AE2 to outside the pixel defining layer PDL, a first light emitting layer EL1 and a first common electrode CE1 on the first pixel electrode AE1, in the first pixel opening, a second light emitting layer EL2 and a second common electrode CE2 on the second pixel electrode AE2, in the second pixel opening, a bank (e.g., the bank structure BNS) on the pixel defining layer PDL, the bank including a first bank layer BN1 including side surfaces respectively defining lower bank openings corresponding to the first and second pixel openings (e.g., volume portion coplanar with BN1, inclusive of EA1 and EA2) and a second bank layer BN2 on the first bank layer BN1, the second bank layer including side surfaces respectively defining upper bank openings corresponding to the lower bank openings (e.g., volume portion coplanar with BN2, inclusive of EA1 and EA2), the side surfaces of the second bank layer BN2 protruding further than the side surfaces of the first bank layer BN1 to define tips of the second bank layer BN2 (e.g., at BN2_TP), and the tips including an upper surface of the second bank layer BN2. a lower inorganic layer TFE1 of an encapsulation layer on the bank, the lower inorganic layer including a first inorganic pattern TL1 including a body portion TL1_B on the first common electrode CE1, and a first wing portion TL1_W1 which overlaps the upper surface the second bank layer BN2 and is spaced apart from the upper surface of the second bank layer BN2, and a second inorganic pattern TL2 including a body portion TL2_B on the second common electrode CE2, a first wing portion TL2_W1 overlapping the first wing portion TL1_W1 of the first inorganic pattern TL1, and a first connection portion TL2_C1 which is connected to the body portion TL2_B and the first wing portion TL2_W1 of the second inorganic pattern TL2 and is between the first wing portion of the first inorganic pattern and the second bank layer BN2.

The first inorganic pattern TL1 may further include a second wing portion TL1_W2 connecting the body portion of the first inorganic pattern and the first wing portion of the first inorganic pattern to each other, the second wing portion spaced apart from the upper surface of the second bank layer, and the first wing portion of the first inorganic pattern protruding further from the second wing portion of the first inorganic pattern, in a direction toward the second inorganic pattern, to overlap the first connection portion of the second inorganic pattern.

The second inorganic pattern TL2 may further include a second wing portion TL2_W2 and a third wing portion TL2_W3 in order from the first wing portion to the first connection portion of the second inorganic pattern, along a thickness direction of the substrate, the second wing portion of the second inorganic pattern protruding further than the third wing portion, in a direction toward the first inorganic pattern, to overlap the first wing portion of the first inorganic pattern, and the first wing portion of the second inorganic pattern protruding further than the second wing portion of the second inorganic pattern in the direction toward the first inorganic pattern, to overlap the first wing portion of the first inorganic pattern.

The second wing portion TL1_W2 of the first inorganic pattern TL1 which is spaced apart from the upper surface of the second bank layer defines a first void space VD1 therebetween, and the first connection portion TL2_C1 of the second inorganic pattern TL2 which is between the first wing portion of the first inorganic pattern and the second bank layer covers the first void space VD1.

The second inorganic pattern TL2 may further include a second connection portion TL2_C2 coplanar with the second wing portion TL1_W2 of the first inorganic pattern TL1, and a third connection portion TL2_C3 connecting the second connection portion of the second inorganic pattern and the body portion of the second inorganic pattern to each other.

A light emitting layer may include the second light emitting layer EL2 and an organic pattern ELP2 which is on the second bank layer and between the first pixel opening EA1 and the second pixel opening EA2, along the substrate. A portion of the second bank layer is between the first pixel opening EA1 and the second pixel opening EA2, and the portion contacts both the third connection portion of the second inorganic pattern and the second organic pattern of the light emitting layer.

At a location between the first pixel opening and the second pixel opening, the first connection portion TL2_C1 of the second inorganic pattern contacts a lower surface of the first wing portion of the first inorganic pattern, and the second connection portion TL2_C2 of the second inorganic pattern contacts an outer side surface of the second wing portion TL1_W2 of the first inorganic pattern.

An organic encapsulation layer TFE2 of the encapsulation layer may be on the lower inorganic layer TFE1. The first wing portion TL2_W1 of the second inorganic pattern is spaced apart from the first wing portion TL1_W1 of the first inorganic pattern along a thickness direction of the substrate, and the organic encapsulation layer extends between the first wing portion of the first inorganic pattern and the first wing portion of the second inorganic pattern.

A method includes providing pixel electrodes of light emitting elements which are spaced apart from each other, a sacrificial layer on each of the pixel electrodes, and a pixel defining material layer on each of the sacrificial layers, on a substrate (FIG. 8), providing a first bank material layer and a second bank material layer, on the pixel defining material layer (FIG. 8), exposing the pixel defining material layer outside the first bank material layer and the second bank material layer, by etching the first bank material layer and the second bank material in areas respectively overlapping the pixel electrodes to provide bank openings of a bank structure at which side surfaces of both the first bank material layer and the second bank material layer are exposed (FIG. 9), etching the side surfaces of the first bank material layer to expose a lower surface of the second bank material layer, at the bank openings, to provide a first bank layer BN1 and a second bank layer BN2 of the bank structure BNS in which the bank openings are defined (FIG. 10), exposing the pixel electrodes to outside the pixel defining layer, by etching the pixel defining material layer which is exposed and etching the sacrificial layers, at the bank openings of the bank structure (FIGS. 11 and 12), providing a first light emitting material layer on the pixel electrodes which are exposed and on the bank structure, the first light emitting material layer including a first light emitting layer EL1 on a first pixel electrode AE1 among the pixel electrodes and a first organic pattern ELPL1 which is separated from the first light emitting layer EL1 and on the bank structure (FIG. 14), providing a first electrode material layer on the first light emitting material layer, the first electrode material layer including a first common electrode CE1 on the first light emitting layer EL1 and a first electrode pattern CEPL1 on the first organic pattern ELPL1 (FIG. 14), providing a first inorganic material layer TLL1 of an encapsulation layer, on the first electrode material layer (FIG. 14), providing a mask pattern PR on the first inorganic material layer which overlaps the first pixel electrode AE1 at a first bank opening among the bank openings and overlaps a first portion of the first inorganic material layer which is adjacent to the first bank opening, the mask pattern exposing a second portion of the first inorganic material layer which is further from the first bank opening than the first portion (FIG. 15), and removing the first portion and the second portion of the first inorganic material layer (FIG. 16).

The removing of the first portion and the second portion of the first inorganic material layer includes isotropic etching, and the isotropic etching provides a first inorganic pattern TL1 covering the first common electrode CE1 and defining a wing portion of the first inorganic pattern TL1 which corresponds to the first portion of the first inorganic material layer and overlaps the bank structure (FIGS. 15 and 16).

The first organic pattern ELPL1 and the first electrode pattern CEPL1 together define a first trace pattern TRP1. The removing of the first portion and the second portion of the first inorganic material layer exposes the first trace pattern TRP1, to outside the first inorganic material layer (FIG. 15). Here, the method may further include removing the first trace pattern TRP1 (FIG. 16), and after the removing of the first trace pattern TRP1, providing a second light emitting material layer on the first inorganic pattern TL1, on the pixel electrodes and on the bank structure, the second light emitting material layer including a second light emitting layer EL2 on a second pixel electrode AE2 among the pixel electrodes and a second organic pattern ELPL2 which is separated from the second light emitting layer EL2 and on the bank structure, providing a second electrode material layer on the second light emitting material layer, the second electrode material layer including a second common electrode CE2 on the second light emitting layer and a second electrode pattern CEPL2 on the second organic pattern ELPL2, and providing a second inorganic material layer TLL2 of the encapsulation layer, on the second electrode material layer, on the first inorganic pattern TL1 and on the bank structure (FIG. 17).

The providing of the second light emitting material layer includes the wing portion of the first inorganic pattern TL1 separating the second light emitting layer into a first pattern on the wing portion (portions of ELPL2 on TL1 in FIG. 17) and a second pattern which is on the bank structure and adjacent to the wing portion (portions of ELPL2 on BN1 in FIG. 17). The providing of the second inorganic material layer includes extending the second inorganic material layer TLL2 between the first pattern and the second pattern of the second light emitting layer and between the wing portion of the first inorganic pattern and the bank structure (e.g., where TLL2 folds onto itself next to TL1, in FIG. 17).

However, the effects of the present disclosure are not restricted to the one set forth herein. The above and other effects of the present disclosure will become more apparent to one of daily skill in the art to which the present disclosure pertains by referencing the claims.

While the present disclosure has been particularly illustrated and described with reference to embodiments thereof, it will be understood by those of ordinary skill in the art that various changes in form and detail may be made therein without departing from the spirit and scope of the present disclosure as defined by the following claims. The embodiments should be considered in a descriptive sense only and not for purposes of limitation.

What is claimed is:

1. A display device comprising:
a first pixel electrode and a second pixel electrode spaced apart from each other on a substrate;
a pixel defining layer disposed on the substrate and exposing the first pixel electrode and the second pixel electrode;
a first light emitting layer on the first pixel electrode and a first common electrode on the first light emitting layer;
a second light emitting layer on the second pixel electrode and a second common electrode on the second light emitting layer;
a first bank layer disposed on the pixel defining layer;
a second bank layer disposed on the first bank layer and comprising side surfaces protruding more than side surfaces of the first bank layer;
a first inorganic layer comprising a body portion disposed on the first common electrode and a first wing portion disposed on the second bank layer but spaced apart from an upper surface of the second bank layer; and
a second inorganic layer comprising a body portion disposed on the second common electrode, a first connection portion disposed between the first wing portion of the first inorganic layer and the second bank layer, and a first wing portion disposed on the first wing portion of the first inorganic layer.

2. The display device of claim 1, wherein the first inorganic layer further comprises a second wing portion connecting the body portion of the first inorganic layer and the first wing portion of the first inorganic layer and spaced apart from the upper surface of the second bank layer, wherein the first wing portion of the first inorganic layer comprises a first side surface overlapping the first light emitting layer and a second side surface opposite the first side surface, the second wing portion of the first inorganic layer comprises a first side surface overlapping the first light emitting layer and a second side surface opposite the first side surface, and the second side surface of the first wing portion of the first inorganic layer protrudes more than the second side surface of the second wing portion of the first inorganic layer.

3. The display device of claim 1, wherein the first wing portion of the second inorganic layer is spaced apart from the first wing portion of the first inorganic layer, along a thickness direction of the substrate.

4. The display device of claim 1, wherein the second inorganic layer further comprises a third wing portion protruding from the first connection portion of the second inorganic layer in a thickness of the substrate and a second wing portion connecting the third wing portion of the second inorganic layer and the first wing portion of the second inorganic layer, wherein the first wing portion of the second inorganic layer comprises a first side surface adjacent to the second light emitting layer and a second side surface opposite the first side surface, the second wing portion of the second inorganic layer comprises a first side surface adjacent to the second light emitting layer and a second side surface opposite the first side surface, and the second side surface of the first wing portion of the second inorganic layer protrudes more than the second side surface of the second wing portion of the second inorganic layer.

5. The display device of claim 2, wherein
the second wing portion of the first inorganic layer which is spaced apart from the upper surface of the second bank layer defines a first void space therebetween, and
the first inorganic layer and the second inorganic layer cover the first void space.

6. The display device of claim 2, wherein the second inorganic layer further comprises a second connection portion connected to the first connection portion of the second inorganic layer and disposed on the second side surface of the second wing portion of the first inorganic layer and a third connection portion connecting the second connection portion of the second inorganic layer and the body portion of the second inorganic layer.

7. The display device of claim 6, further comprising a second organic pattern disposed on the second bank layer and comprising the same material as the second light emitting layer, wherein a portion of the second bank layer contacts the third connection portion of the second inorganic layer, and another portion of the second bank layer contacts the second organic pattern.

8. The display device of claim 6, wherein the first connection portion of the second inorganic layer contacts a lower surface of the first wing portion of the first inorganic layer, and the second connection portion of the second inorganic layer contacts the second side surface of the second wing portion of the first inorganic layer.

9. The display device of claim 2, wherein a thickness of the first wing portion of the first inorganic layer is smaller than a thickness of the second wing portion of the first inorganic layer.

10. The display device of claim 1, wherein a distance between the first wing portion of the first inorganic layer and the first wing portion of the second inorganic layer is greater than a distance between the second pixel electrode and the body portion of the second inorganic layer.

11. The display device of claim 2, wherein a distance between the second bank layer and the second wing portion of the first inorganic layer is equal to a distance between the first pixel electrode and the body portion of the first inorganic layer.

12. The display device of claim 1, further comprising an organic encapsulation layer disposed between the first wing portion of the first inorganic layer and the first wing portion of the second inorganic layer.

13. The display device of claim 1, wherein the body portion of the first inorganic layer comprises silicon (Si), oxygen (O) and nitrogen (N), and the first wing portion of the first inorganic layer comprises silicon (Si) and oxygen (O).

14. The display device of claim 8, wherein the first wing portion of the first inorganic layer comprises silicon (Si) and oxygen (O), and the first connection portion of the second inorganic layer comprises silicon (Si) and nitrogen (N).

15. The display device of claim 1, wherein the first common electrode and the second common electrode are spaced apart from each other and contact the side surfaces of the first bank layer.

16. The display device of claim 1, further comprising residual patterns disposed between the pixel defining layer and the first pixel electrode and between the pixel defining layer and the second pixel electrode.

17. A method of providing a display device, the method comprising:
providing pixel electrodes of light emitting elements which are spaced apart from each other, a sacrificial layer on each of the pixel electrodes, and a pixel defining material layer on each of the sacrificial layers, on a substrate;
providing a first bank material layer and a second bank material layer, on the pixel defining material layer;
exposing the pixel defining material layer outside the first bank material layer and the second bank material layer, by etching the first bank material layer and the second bank material layer in areas respectively overlapping the pixel electrodes to provide bank openings of a bank structure at which side surfaces of both the first bank material layer and the second bank material layer are exposed;
etching the side surfaces of the first bank material layer to expose a lower surface of the second bank material layer, at the bank openings, to provide a first bank layer and a second bank layer of the bank structure in which the bank openings are defined;
exposing the pixel electrodes to outside the pixel defining layer, by etching the pixel defining material layer which is exposed and etching the sacrificial layers, at the bank openings of the bank structure;
providing a first light emitting material layer on the pixel electrodes which are exposed and on the bank structure, the first light emitting material layer including a first light emitting layer on a first pixel electrode among the pixel electrodes and a first organic pattern which is separated from the first light emitting layer and on the bank structure;
providing a first electrode material layer on the first light emitting material layer, the first electrode material layer including a first common electrode on the first light emitting layer and a first electrode pattern on the first organic pattern;
providing a first inorganic material layer of an encapsulation layer, on the first electrode material layer;
providing a mask pattern on the first inorganic material layer which overlaps the first pixel electrode at a first bank opening among the bank openings and overlaps a first portion of the first inorganic material layer which is adjacent to the first bank opening, the mask pattern exposing a second portion of the first inorganic material layer which is further from the first bank opening than the first portion; and
removing the first portion and the second portion of the first inorganic material layer.

18. The method of claim 17, wherein
the first inorganic material layer includes silicon nitride or silicon oxynitride,
the removing of the first portion and the second portion of the first inorganic material layer includes isotropic etching, and
the isotropic etching provides a first inorganic pattern covering the first common electrode and defining a wing portion of the first inorganic pattern which corresponds to the first portion of the first inorganic material layer and overlaps the bank structure.

19. The method of claim 18, wherein
the first organic pattern and the first electrode pattern together define a first trace pattern, and
the removing of the first portion and the second portion of the first inorganic material layer exposes the first trace pattern, to outside the first inorganic material layer,
the method further comprising:
removing the first trace pattern; and
after the removing of the first trace pattern:
providing a second light emitting material layer on the first inorganic pattern, on the pixel electrodes and on the bank structure, the second light emitting material layer including a second light emitting layer on a second pixel electrode among the pixel electrodes and a second organic pattern which is separated from the second light emitting layer and on the bank structure;
providing a second electrode material layer on the second light emitting material layer, the second electrode material layer including a second common electrode on the second light emitting layer and and a second electrode pattern on the second organic pattern; and
providing a second inorganic material layer of the encapsulation layer, on the second electrode material layer, on the first inorganic pattern and on the bank structure.

20. The method of claim 19, wherein
the providing of the second light emitting material layer comprises the wing portion of the first inorganic pattern separating the second light emitting layer into a first pattern on the wing portion and a second pattern which is on the bank structure and adjacent to the wing portion, and
the providing of the second inorganic material layer comprises extending the second inorganic material layer between the first pattern and the second pattern of the second light emitting layer and between the wing portion of the first inorganic pattern and the bank structure.
